(19) United States
(12) Patent Application Publication
(10) Pub. No.: US 2025/0125693 A1
(43) Pub. Date: Apr. 17, 2025

(54) SEMICONDUCTOR DEVICE

(71) Applicant: FUJI ELECTRIC CO., LTD., Kawasaki-shi (JP)

(72) Inventor: Shigemi MIYAZAWA, Matsumoto-city (JP)

(73) Assignee: FUJI ELECTRIC CO., LTD., Kawasaki-shi (JP)

(21) Appl. No.: 18/816,211

(22) Filed: Aug. 27, 2024

(30) Foreign Application Priority Data
Oct. 12, 2023 (JP) 2023-176768
Mar. 4, 2024 (JP) 2024-032078

(51) Int. Cl. H02K 11/33; H01L 23/00; H01L 23/495

(52) U.S. Cl. CPC H02K 11/33; H01L 23/49575; H01L 24/48; H01L 2224/48137; H01L 2224/48157; H01L 2224/48245; H01L 2924/1426

(57) ABSTRACT

A semiconductor device includes: a first switching element provided in a first semiconductor chip; a first control circuit provided in a second semiconductor chip so as to output a signal for controlling the first switching element; a level-shift circuit provided to convert a potential of the signal output from the first control circuit; and a drive circuit provided in a third semiconductor chip so as to drive the first switching element in accordance with the signal with the potential converted by the level-shift circuit, wherein the third semiconductor chip is provided on the first semiconductor chip.

### CROSS-REFERENCE TO RELATED APPLICATION

This application claims benefit of priority under 35 USC 119 based on Japanese Patent Applications No. 2023-176768 filed on Oct. 12, 2023, and No. 2024-032078 filed on Mar. 4, 2024, the entire contents of which are incorporated by reference herein.

### BACKGROUND OF THE INVENTION

### 1. Field of the Invention

The present disclosure relates to semiconductor devices.

### 2. Description of the Related Art

JP2001-237381A discloses a semiconductor device including a GND reference circuit and a floating reference circuit provided in different semiconductor substrates. JP2010-154721A discloses a semiconductor device including a GND reference circuit provided in a first substrate and a floating reference circuit in a second substrate.

JP2004-120917A discloses an inverter device including a first semiconductor chip including an upper-arm drive circuit and a current detecting circuit, a second semiconductor chip including a lower-arm drive circuit and a drive-signal processing circuit, and a third semiconductor chip including a high-voltage MOSFET for a level-shift circuit.

JP2004-265931A discloses a semiconductor-element-driving integrated circuit, the integrated circuit being implemented such that a circuit element for supplying driving power to a semiconductor element is installed in a semiconductor chip different from a semiconductor chip provided with another circuit element.

Conventional semiconductor devices such as an inverter for driving a motor have a configuration for ensuring a high power-supply voltage so as to reduce a power loss derived from current and further achieve a reduction in size while keeping a motor output. Thus, demand for promoting high-voltage integrated circuits (HVIC) for driving power semiconductor elements on a high-potential side has been increased. However, leading such a HVIC to have higher breakdown voltage needs to include a semiconductor substrate having a greater area, which results in an increase in manufacturing cost.

### SUMMARY OF THE INVENTION

In view of the foregoing problems, the present disclosure provides a semiconductor device having a configuration capable of ensuring high breakdown voltage without an area of a semiconductor substrate increased.

An aspect of the present disclosure inheres in a semiconductor device including: a first switching element provided in a first semiconductor chip; a first control circuit provided in a second semiconductor chip so as to output a signal for controlling the first switching element; a level-shift circuit provided to convert a potential of the signal output from the first control circuit; and a drive circuit provided in a third semiconductor chip so as to drive the first switching element in accordance with the signal with the potential converted by the level-shift circuit, wherein the third semiconductor chip is provided on the first semiconductor chip.

Another aspect of the present disclosure inheres in a semiconductor device including: a first switching element provided in a first semiconductor chip; a first control circuit provided in a second semiconductor chip so as to output a signal for controlling the first switching element; a level-shift circuit provided to convert a potential of the signal output from the first control circuit; a drive circuit provided in a third semiconductor chip so as to drive the first switching element in accordance with the signal with the potential converted by the level-shift circuit; and a relay wiring element arranged between the first semiconductor chip and the third semiconductor chip so as to be electrically connected to at least any of the first semiconductor chip, the second semiconductor chip, and the third semiconductor chip.

Further aspect of the present disclosure inheres in a semiconductor device including: a first switching element provided in a first semiconductor chip; a first control circuit provided in a second semiconductor chip so as to output a signal for controlling the first switching element; a level-shift circuit provided to convert a potential of the signal output from the first control circuit; a drive circuit provided in a third semiconductor chip so as to drive the first switching element in accordance with the signal with the potential converted by the level-shift circuit; a plurality of terminals electrically connected to the drive circuit; and a wired substrate arranged on the plural terminals and electrically connected to at least either the second semiconductor chip or the third semiconductor chip.

It should be noted that the above summary of the invention does not list all the necessary features of the present disclosure. Subcombinations of these feature groups can also be inventions.

### BRIEF DESCRIPTION OF THE DRAWINGS

FIG. 1 is a circuit diagram illustrating an example of a configuration of a rotating machine according to a first embodiment;

FIG. 2 is a circuit diagram illustrating an example of a configuration of a semiconductor device according to the first embodiment;

FIG. 3 is a circuit diagram illustrating an example of a configuration of the semiconductor device according to the first embodiment;

FIG. 4 is a circuit diagram illustrating an example of a configuration of the semiconductor device according to the first embodiment;

FIG. 5 is a circuit diagram illustrating an example of a configuration of an upper-arm control circuit according to the first embodiment;

FIG. 6 is a circuit diagram illustrating an example of a configuration of a drive circuit according to the first embodiment;

FIG. 7 is a circuit diagram illustrating an example of a configuration of a lower-arm control circuit according to the first embodiment;

FIG. 8 is a circuit diagram illustrating an example of a configuration of an inverter according to the first embodiment;

FIG. 9 is a circuit diagram illustrating an example of a configuration of an inverter according to the first embodiment;

FIG. 10 is a circuit diagram illustrating an example of a configuration of a NAND circuit according to the first embodiment;

FIG. 11 is a timing chart showing an example of timing during a switching operation of the semiconductor device according to the first embodiment;

FIG. 12 is a cross-sectional view illustrating an example of a structure of a main part of the semiconductor device according to the first embodiment;

FIG. 13 is a cross-sectional view illustrating an example of the structure of the main part of the semiconductor device according to the first embodiment;

FIG. 14 is a cross-sectional view illustrating a structure of a main part of a semiconductor device of a comparative example;

FIG. 15 is a circuit diagram illustrating an example of a configuration of the semiconductor device according to the first embodiment;

FIG. 16 is a plan view illustrating an example of a packaged configuration of the semiconductor device according to the first embodiment;

FIG. 17 is a plan view illustrating a packaged configuration of a semiconductor device of a comparative example;

FIG. 18 is a plan view illustrating an example of a packaged configuration of a semiconductor device according to a second embodiment;

FIG. 19 is a plan view illustrating an example of a packaged configuration of a semiconductor device according to a third embodiment;

FIG. 20 is a plan view illustrating an example of a packaged configuration of a semiconductor device according to a fourth embodiment;

FIG. 21 is a plan view illustrating an example of a packaged configuration of a semiconductor device according to a fifth embodiment;

FIG. 22 is a plan view illustrating an example of a packaged configuration of a semiconductor device according to a sixth embodiment;

FIG. 23 is a plan view illustrating an example of a packaged configuration of a semiconductor device according to a seventh embodiment;

FIG. 24 is a cross-sectional view illustrating an example of components in the packaged configuration illustrated in FIG. 23;

FIG. 25 is a circuit diagram illustrating an example of the components in the packaged configuration illustrated in FIG. 23;

FIG. 26 is a plan view illustrating an example of a packaged configuration of a semiconductor device according to an eighth embodiment;

FIG. 27 is a cross-sectional view illustrating an example of components in the packaged configuration illustrated in FIG. 26;

FIG. 28 is a plan view illustrating an example of a packaged configuration of a semiconductor device according to a ninth embodiment; and

FIG. 29 is a plan view illustrating an example of a packaged configuration of a semiconductor device according to a tenth embodiment.

### DETAILED DESCRIPTION

With reference to the drawings, first to tenth embodiments of the present disclosure will be described below.

In the drawings, the same or similar elements are indicated by the same or similar reference numerals. The drawings are schematic, and it should be noted that the relationship between thickness and planer dimensions, the thickness proportion of each layer, and the like are different from real ones. Moreover, in some drawings, portions are illustrated with different dimensional relationships and proportions. The first to tenth embodiments described below merely illustrate schematically devices and methods for specifying and giving shapes to the technical idea of the present disclosure, and the span of the technical idea is not limited to materials, shapes, structures, and relative positions of elements described herein.

In the specification, definitions of directions such as an up-and-down direction in the following description are merely definitions for convenience of understanding, and are not intended to limit the technical ideas of the present disclosure. For example, as a matter of course, when the subject is observed while being rotated by 90°, the subject is understood by converting the up-and-down direction into the right-and-left direction. When the subject is observed while being rotated by 180°, the subject is understood by inverting the up-and-down direction.

The term “connection” or “connected” as used in the present specification refers to a state of “electrical connection” or “being electrically connected” unless otherwise specified. In addition, the present specification defines a voltage or a signal as a “low (Lo) level” when a logic level is low, and defines as a high (Hi) level” when the logic level is high. A ground potential as used herein is a reference potential of the entire system including semiconductor devices, which is zero.

### First Embodiment

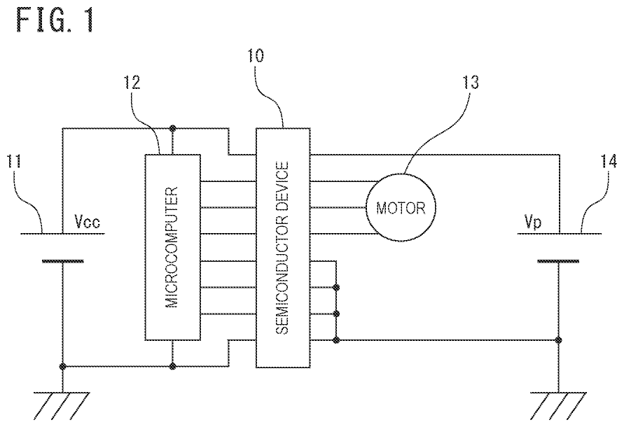

FIG. 1 is a diagram illustrating a schematic configuration of a rotating machine in which a semiconductor device 10 according to a first embodiment is used. The semiconductor device 10 is connected to a power source 11, a microcomputer 12, a motor 13, and another power source 14. The power source 11 supplies a power-supply potential Vcc. The power source 11 is a battery for a vehicle with the power-supply potential Vcc of 14 volts, for example.

The microcomputer 12 outputs signals Sinhu, Sinlu, Sinhv, Sinlv, Sinhw, and Sinlw for controlling the motor 13. The microcomputer 12 is a device included in an electronic control unit (ECU) for a vehicle, for example. The motor 13 is a three-phase AC motor having a U-phase, a V-phase, and a W-phase, for example. The power source 14 supplies a power-supply potential Vp. The power source 14 is a battery for a vehicle with the power-supply potential Vp of 400 volts, for example.

The semiconductor device 10 is an inverter that drives the motor 13 with the power-supply potential Vp supplied from the power source 14 in accordance with the power-supply potential VCC supplied from the power source 11 and the signals Sinhu, Sinlu, Sinhv, Sinlv, Sinhw, and Sinlw output from the microcomputer 12.

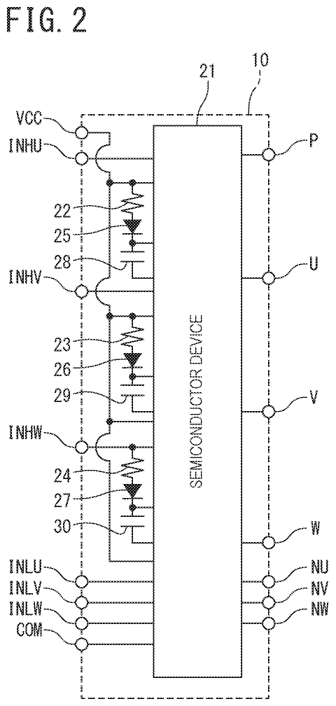

FIG. 2 is a diagram illustrating a schematic configuration of the semiconductor device 10. The semiconductor device 10 includes terminals VCC, INHU, INHV, INHW, INLU, INLV, INLW, COM, P, U, V, W, NU, NV, and NW. The power-supply potential Vcc from the power source 11 is applied to the terminal VCC. The signals Sinhu, Sinhv, Sinhw, Sinlu, Sinlv, and Sinlw are respectively input to the terminals INHU, INHV, INHW, INLU, INLV, and INLW from the microcomputer 12. The power-supply potential Vp from the power source 14 is applied to the terminal P. The ground potential is applied to the terminal COM.

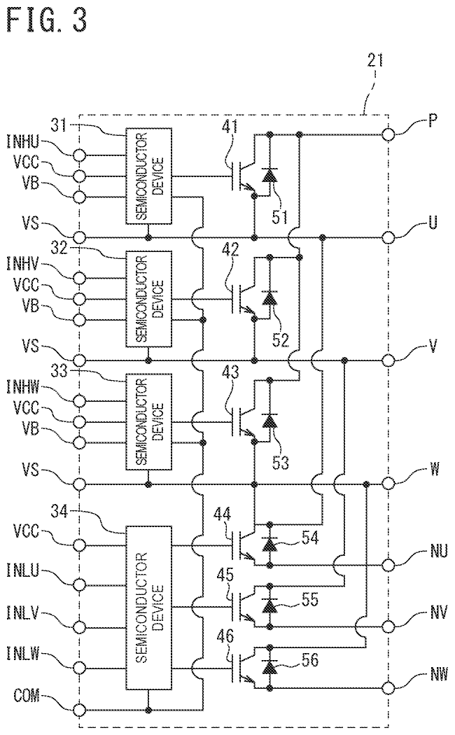

The semiconductor device 10 includes a semiconductor device 21, resistors 22 to 24, diodes 25 to 27, and capacitors 28 to 30. The resistors 22 to 24, the diodes 25 to 27, and the capacitors 28 to 30 implement a bootstrap circuit to charge the capacitors 28 to 30 to a voltage equivalent to the power-supply voltage Vcc when a potential of each of the terminals VS(U), VS(V), and VS(W) included in the semiconductor device 21 (refer to FIG. 3) is at a Lo level.

FIG. 3 is a diagram illustrating a schematic configuration of the semiconductor device 21 illustrated in FIG. 2. The semiconductor device 21 includes terminals INHU, VCC, VB(U), VS(U), INHV, VB(V), VS(V), INHW, VB(W), VS(W), INLU, INLV, INLW, COM, P, U, V, W, NU, NV, and NW. The terminal VB(U) is connected between a cathode of the diode 25 and one end of the capacitor 28 illustrated in FIG. 2. The terminal VS(U) is connected to the other end of the capacitor 28 illustrated in FIG. 2. The terminal VB(V) is connected to a cathode of the diode 26 and one end of the capacitor 29 illustrated in FIG. 2. The terminal VS(V) is connected to the other end of the capacitor 29 illustrated in FIG. 2. The terminal VB(W) is connected between a cathode of the diode 27 and one end of the capacitor 30 illustrated in FIG. 2. The terminal VS(W) is connected to the other end of the capacitor 30 illustrated in FIG. 2.

The semiconductor device 21 further includes semiconductor devices 31 to 34, switching elements (first switching elements) 41 to 43, switching elements (second switching elements) 44 to 46, and freewheeling diodes (FWDs) 51 to 56. The switching elements 41 to 43 are provided on a high-potential side, and the switching elements 44 to 46 are provided on a low-potential side. The semiconductor device 34 is implemented by a low-voltage integrated circuit (LVIC). The semiconductor device 34 outputs signals for controlling the switching elements 44 to 46 to the respective gates of the switching elements 44 to 46 to drive the switching elements 44 to 46, so as to control current flowing through the respective switching elements 44 to 46. The semiconductor devices 31 to 33 are each implemented by a high-voltage integrated circuit (HVIC). The semiconductor devices 31 to 33 output signals for controlling the switching element 41 to 43 to the gates of the switching elements 41 to 43, so as to control current flowing through the respective switching elements 41 to 43. The semiconductor devices 31 to 33 can have a common configuration, and the following explanations are made with regard to a configuration of the semiconductor device 31.

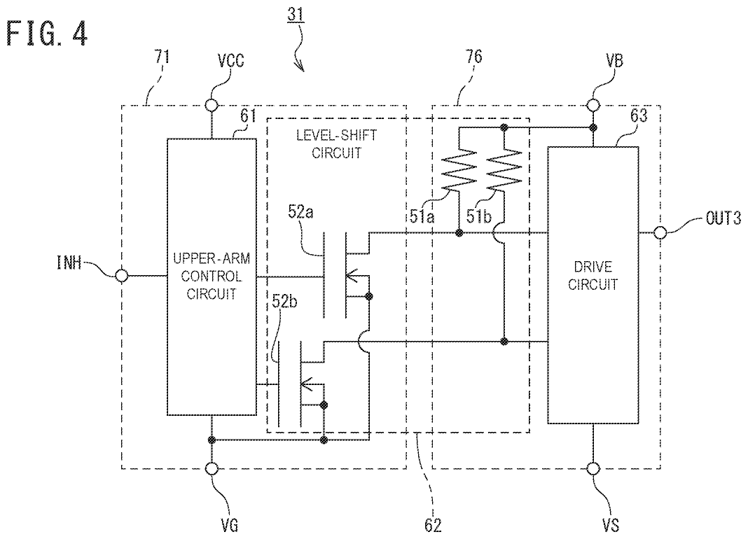

FIG. 4 is a diagram illustrating a schematic configuration of the semiconductor device 31 illustrated in FIG. 3. The semiconductor device 31 includes terminals VCC, INH, VB, VS, VG, and OUT3. The terminal VG is connected to the terminal COM illustrated in FIG. 3. The terminal OUT3 is connected to the gate of the switching element 41 illustrated in FIG. 3. The semiconductor device 31 includes an upper-arm control circuit (a first control circuit) 61 serving as a low-voltage part, a level-shift circuit 62, and a drive circuit 63 serving as a high-voltage part. The upper-arm control circuit 61 operates with the power-supply potential VCC higher than the ground potential as power-supply potential. The upper-arm control circuit 61 outputs signals for controlling the switching element 41. The level-shift circuit 62 executes a signal-voltage conversion between the upper-arm control circuit 61 and the drive circuit 63. The level-shift circuit 62 converts a potential of a signal based on the ground potential output from the upper-arm control circuit 61, and outputs a signal based on a VS potential applied to the terminal VS to the drive circuit 63. The drive circuit 63 operates, on the basis of the VS potential which is a floating potential during operation, by use of the power-supply potential VB higher than the VS potential as a power-supply potential. The drive circuit 63 drives the switching element 41 in accordance with the signal with the potential converted by the level-shift circuit 62. As schematically indicated by the broken line in FIG. 4, the upper-arm control circuit 61 and MOS transistors 52a and 52b of the level-shift circuit 62 are provided in a semiconductor substrate 71 described below. Further, as schematically indicated by the broken line in FIG. 4, the drive circuit 63 and resistors 51a and 51b of the level-shift circuit 62 is provided in a semiconductor substrate 76 described below.

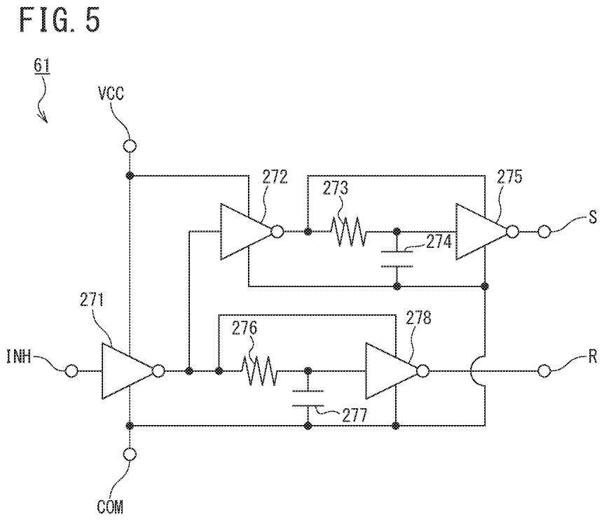

FIG. 5 is a diagram illustrating a schematic configuration of the upper-arm control circuit 61 illustrated in FIG. 4. The upper-arm control circuit 61 includes terminals VCC, COM, INH, S, and R. The terminal COM is connected to the terminal VG illustrated in FIG. 4. The terminals S and R are connected to the gates of the respective MOS transistors 52a and 52b illustrated in FIG. 4. The upper-arm control circuit 61 further includes inverters 271, 272, 275, and 278, resistors 273 and 276, and capacitors 274 and 277. The resistors 273 and 276 and the capacitors 274 and 277 implement a delay circuit. When an output voltage level of the respective inverters 271 and 272 is changed, an input voltage level of the respective inverters 275 and 278 is changed at a delayed timing.

The upper-arm control circuit 61 outputs a pulse signal based on a signal Sinh input to the terminal INH from the microcomputer 12. For example, when a voltage of the signal Sinh is increased from less than 2.5 volts to 2.5 volts or higher, the upper-arm control circuit 61 outputs a voltage pulse at a Hi level from the terminal S. The voltage pulse is changed to the Lo level after a lapse of a predetermined time (for example, 0.1 μs). When the voltage of the signal Sinh is decreased from 2.5 volts or higher to less than 2.5 volts, the upper-arm control circuit 61 outputs a voltage pulse at a Hi level from the terminal R. When the voltage level of the signal Sinh is not changed, the voltage level of the respective terminals S and R is at the Lo level.

The resistor 51a and the MOS transistor 52a and the resistor 51b and the MOS transistor 52b illustrated in FIG. 4 serve as a level-shift circuit. The MOS transistors 52a and 52b are each an n-type MOS transistor, for example. When a gate voltage of the respective MOS transistors 52a and 52b is at a Hi level, a drain voltage of the respective MOS transistors 52a and 52b has the same potential as the terminal VG. When the gate voltage of the respective MOS transistors 52a and 52b is at a Lo level, the drain voltage of the respective MOS transistors 52a and 52b has the same potential as the terminal VB.

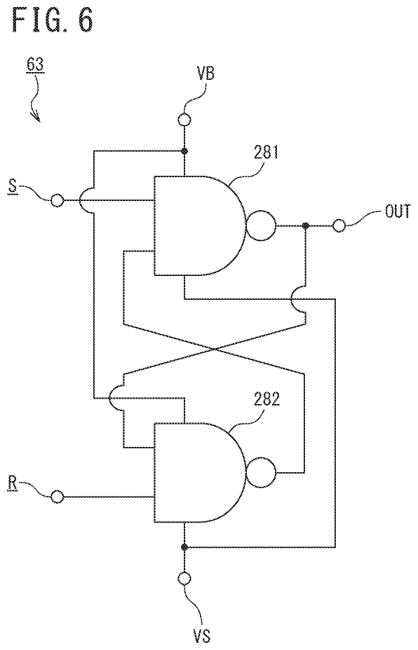

FIG. 6 is a diagram illustrating a schematic configuration of the drive circuit 63 illustrated in FIG. 4. The drive circuit 63 includes terminals VB, VS, S, R, and OUT, and NAND circuits 281 and 282. The terminal S is connected to the drain of the MOS transistor 52a illustrated in FIG. 4. The terminal R is connected to the drain of the MOS transistor 52b illustrated in FIG. 4. The terminal OUT is connected to the terminal OUT3 illustrated in FIG. 4. The drive circuit 63 serves as an RS latch circuit. The voltage level of the respective terminals S and R is at the Hi level in a normal state. When the signal Sin of the terminal INH of the upper-arm control circuit 61 is shifted from the Lo level to the Hi level, a pulse signal at the Lo level is input to the terminal S, while a voltage level of the terminal OUT is led to the Hi level. When the voltage of the terminal OUT is at the Hi level, the switching element 41 to which the terminal OUT is connected is turned ON.

In addition, when the signal Sin of the terminal INH of the upper-arm control circuit 61 is shifted from the Hi level to the Lo level, a pulse signal at the Lo level is input to the terminal R, while the voltage level of the terminal OUT is led to the Lo level. When the voltage of the terminal OUT is at the Lo level, the switching element 41 to which the terminal OUT is connected is turned OFF.

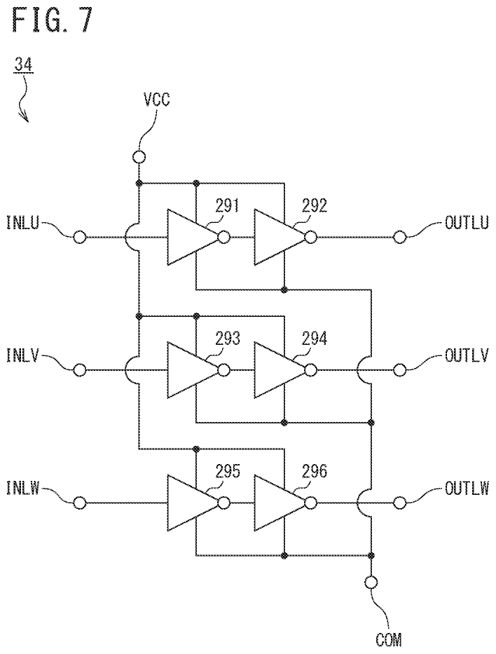

FIG. 7 is a diagram illustrating a schematic configuration of the semiconductor device (the lower-arm control circuit) 34 illustrated in FIG. 3. The lower-arm control circuit (the second control circuit) 34 includes terminals VCC, COM, INLU, INLV, INLW, OUTLU, OUTLV, and OUTLW, and inverters 291 to 296. The terminals OUTLU, OUTLV, and OUTLW are connected to the gates of the respective switching elements 44 to 46 illustrated in FIG. 3. The lower-arm control circuit 34 leads the switching elements 44 to 46 to be turned ON/OFF in accordance with the signal Sinl input to the respective terminals INLU, INLV, and INLW from the microcomputer 12.

The respective switching elements 41 to 46 illustrated in FIG. 3 execute the operation of switching the voltage applied from the power source 14 to the motor 13. The switching elements 41 to 46 are each a high-voltage switching element, for example. The first embodiment is illustrated with a case in which the switching elements 41 to 46 are each a vertical n-channel insulated gate bipolar transistor (IGBT) including an emitter electrode on the front surface side of the substrate and a collector electrode on the rear surface side of the substrate. The switching elements 41 to 46 are each a switching element having an ON resistance of 10 mΩ and a breakdown voltage of several hundreds of volts, for example. The respective switching elements 41 to 46 as used herein are not limited to the IGBT, and may be a MOS transistor or a bipolar transistor.

The FWDs 51 to 56 lead the current flowing through the motor 13 to flow back when the respective switching elements 41 to 46 are in the OFF state. The FWDs 51 to 56 are each a high-voltage diode element, for example. The FWDs 51 to 56 are not necessarily provided when the respective switching elements 41 to 46 are a MOS transistor or a bipolar transistor.

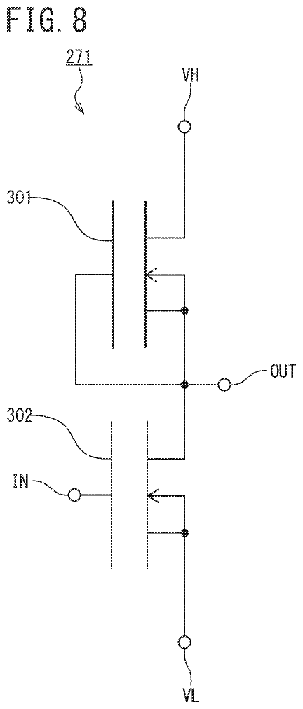

FIG. 8 is a diagram illustrating a schematic configuration of the inverter 271 illustrated in FIG. 5. The inverter 271 includes terminals IN, OUT, VH, and VL, and MOS transistors 301 and 302. The terminal IN is connected to the terminal INH illustrated in FIG. 5. The terminal OUT is connected to one end of the resistor 276 and the inverters 272 and 278 illustrated in FIG. 5. The terminal VH is connected to the terminal VCC illustrated in FIG. 5. The terminal VL is connected to the terminal COM illustrated in FIG. 5. The MOS transistor 301 is a depletion-type MOS transistor. The MOS transistor 302 is an n-channel MOS transistor. The respective inverters 291, 293, and 295 illustrated in FIG. 7 have substantially the same configuration as the inverter 271 illustrated in FIG. 8, and overlapping explanations are not repeated below.

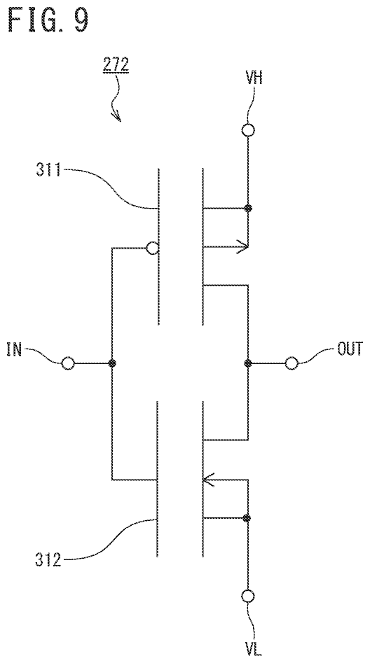

FIG. 9 is a diagram illustrating a schematic configuration of the inverter 272 illustrated in FIG. 5. The inverter 272 includes terminals IN, OUT, VH, and VL, and MOS transistors 311 and 312. The terminal IN is connected to the inverters 271 and 278 and one end of the resistor 276 illustrated in FIG. 5. The terminal OUT is connected to one end of the resistor 273 and the inverter 275 illustrated in FIG. 5. The terminal VH is connected to the terminal VCC illustrated in FIG. 5. The terminal VL is connected to the terminal COM illustrated in FIG. 5. The MOS transistor 311 is a p-channel MOS transistor. The MOS transistor 312 is an n-channel MOS transistor. The respective inverters 275 and 278 illustrated in FIG. 5 and the respective inverters 292, 294, and 296 illustrated in FIG. 7 have substantially the same configuration as the inverter 272 illustrated in FIG. 9, and overlapping explanations are not repeated below.

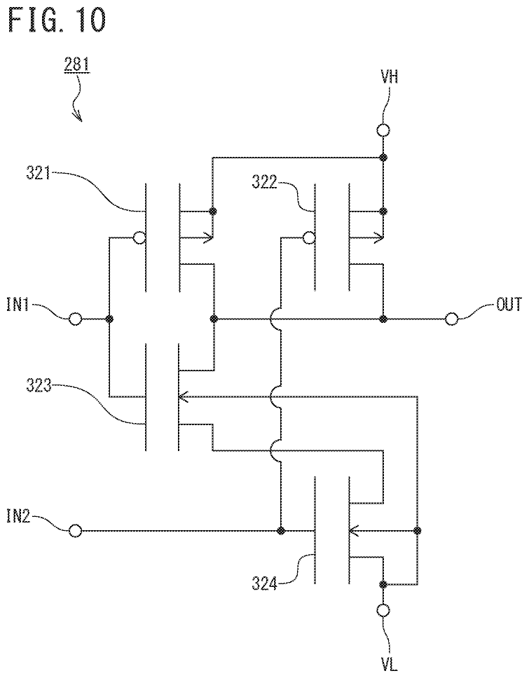

FIG. 10 is a diagram illustrating a schematic configuration of the NAND circuit 281 illustrated in FIG. 6. The NAND circuit 281 includes terminals IN1, IN2, OUT, VH, and VL, and MOS transistors 321 to 324. The terminal IN1 is connected to the terminal S illustrated in FIG. 6. The terminal IN2 is connected to the output side of the NAND circuit 282 illustrated in FIG. 6. The terminal VH is connected to the terminal VB illustrated in FIG. 6. The terminal VL is connected to the terminal VS illustrated in FIG. 6. The MOS transistors 321 and 322 are each a p-channel MOS transistor. The MOS transistors 323 and 324 are each an n-channel MOS transistor. The NAND circuit 282 illustrated in FIG. 6 has substantially the same configuration as the NAND circuit 281 illustrated in FIG. 10, and overlapping explanations are not repeated below.

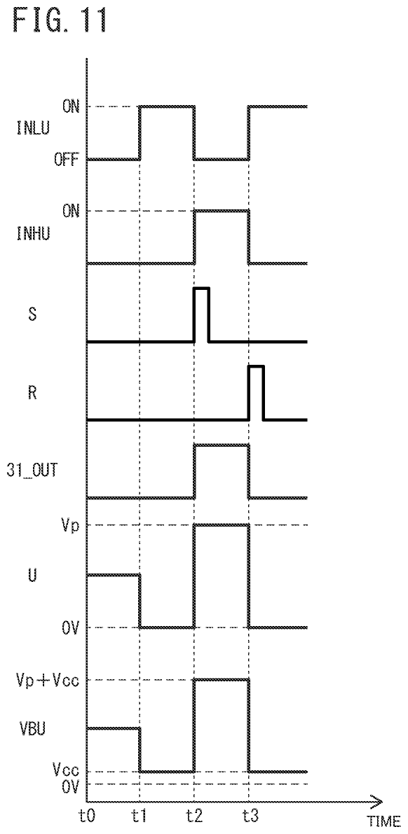

FIG. 11 is an example of a timing chart showing a change in voltage and signal with the lapse of time in the respective semiconductor devices 31 and 34 when the U-phase of the semiconductor device 10 is in switching operation. The term “switching operation” of the U-phase of the semiconductor device 10 as used in the present specification refers to a state in which the respective switching elements 41 and 44 are turned ON/OFF. FIG. 11 is the schematic timing chart of the voltages and signals defined as a “Lo level” when the logic level is low and defined as a “Hi level” when the logic level is high.

At time t0, a signal SIL input to the terminal INLU from the microcomputer 12 and a signal S1H input to the terminal INHU are each at the Lo level, while the respective switching elements 41 and 44 are in the OFF state. A potential of the terminal U at this point is substantially half of a voltage Vp of the power source 14.

At time t1, the microcomputer 12 increases the signal SIL input to the terminal INLU from the Lo level to the Hi level in order to turn the switching element 44 ON. When the switching element 44 is turned ON, the potential of the terminal U is led to be equal to a potential of the grounded terminal NU, and the potential of the terminal VB is substantially equal to the power-supply potential Vcc of the power source 11 through the resistor 22 and the diode 25.

At time t2, the microcomputer 12 decreases the signal SIL input to the terminal INLU from the Hi level to the Lo level and increases the S1H input to the terminal INHU from the Lo level to the Hi level in order to turn the switching element 44 OFF and turn the switching element 41 ON. When the switching element 44 is turned OFF and the switching element 41 is turned ON, the potential of the terminal U is led to be equal to the voltage Vp of the power source 14, and the potential of the terminal VB is led to be equal to Vcc+Vp.

At time t3, the microcomputer 12 increases the signal SIL input to the terminal INLU from the Lo level to the Hi level and decreases the signal S1H input to the terminal INHU from the Hi level to the Lo level in order to turn the switching element 44 ON and the turn the switching element 41 OFF. When the switching element 44 is turned ON and the switching element 41 is turned OFF, the potential of the terminal U is led to be equal to the potential of the terminal NU, and the potential of the terminal VB is led to be equal to Vcc.

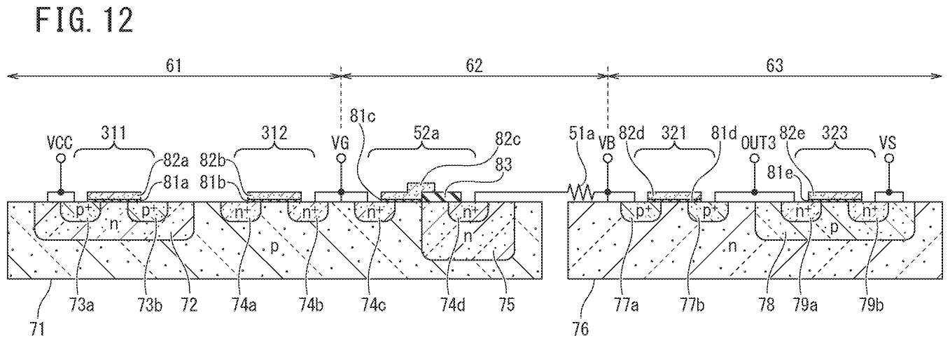

FIG. 12 is a cross-sectional view illustrating an example of a structure of a main part of the semiconductor device 31. The semiconductor device 31 includes semiconductor substrates (also referred to below as “semiconductor chips”) 71 and 76 provided separately from each other. The semiconductor device 31 includes the semiconductor substrate 71 of p-type, and the semiconductor substrate 76 of n-type provided separately from the semiconductor substrate 71. The semiconductor substrate 71 is provided with the upper-arm control circuit 61 and the MOS transistor 52a of the level-shift circuit 62. The semiconductor substrate 76 is provided with the drive circuit 63 and the resistor 51a of the level-shift circuit 62. The upper-arm control circuit 61 and the drive circuit 63 are thus provided in the different semiconductor substrates 71 and 76.

As illustrated in FIG. 12, the semiconductor substrate 71 is provided with the MOS transistors 311 and 312 included in the inverter 272 of the upper-arm control circuit 61, and the MOS transistor 52a included in the level-shift circuit 62. Although not illustrated in FIG. 12, the MOS transistor 52b included in the level-shift circuit 62 having substantially the same configuration as the MOS transistor 52a is also provided in the semiconductor substrate 71.

A well region 72 of n-type, which is an element included in the MOS transistor 311 of the upper-arm control circuit 61, is provided at the upper part of the semiconductor substrate 71. A drain region 73a of p⁺-type and a source region 73b of p⁺-type are provided separately from each other at the upper part of the n-type well region 72. A gate electrode 82a is deposited on a part of the top surface side of the n-type well region 72 with the gate insulating film 81a interposed across the drain region 73a and the source region 73b. The drain region 73a and the source region 73b are formed by ion implantation by use of the gate insulating film 81a and the gate electrode 82a as a mask.

A drain region 74a of n⁺-type and a source region 74b of n⁺-type, which are elements included in the MOS transistor 312 of the upper-arm control circuit 61, are provided separately from each other at the upper part of the semiconductor substrate 71. A gate electrode 82b is deposited on a part of the top surface side of the semiconductor substrate 71 with the gate insulating film 81b interposed across the drain region 74a and the source region 74b. The drain region 74a and the source region 74b are formed by ion implantation by use of the gate insulating film 81b and the gate electrode 82b as a mask.

A source region 74c of n⁺-type, which is an element included in the MOS transistor 52a of the level-shift circuit 62, is provided at the upper part of the semiconductor substrate 71. A high-voltage well region 75 of n-type is provided at the upper part of the semiconductor substrate 71 separately from the source region 74c. A drain region 74d of n⁺-type is provided at the upper part of the n-type high-voltage well region 75. An insulating film 83 is deposited on a part of the top surface side of the n-type high-voltage well region 75. A gate electrode 82c is deposited on a part of the top surface side of the semiconductor substrate 71 with the gate insulating film 81c interposed across the source region 74c and the n-type high-voltage well region 75. The source region 74c and the drain region 74d are formed by ion implantation by use of the insulating film 83, the gate insulating film 81c, and the gate electrode 82c as a mask.

The lower-arm control circuit 34 may be provided integrally in the semiconductor substrate 71. Alternatively, the upper-arm control circuit 61 and the respective MOS transistors 52a and 52b of the level-shift circuit 62 of the respective semiconductor substrates 32 and 33 may be provided integrally in the semiconductor substrate 71. Alternatively, the upper-arm control circuit 61, the respective MOS transistors 52a and 52b of the level-shift circuit 62, and the lower-arm control circuit 34 of the respective semiconductor substrates 32 and 33 may be provided integrally in the semiconductor substrate 71.

On the other hand, the semiconductor substrate 76 is provided with the MOS transistors 321 and 323 of the NAND circuit 281 of the drive circuit 63. Although not illustrated in FIG. 12, the MOS transistor 322 of the NAND circuit 281 of the drive circuit 63 having substantially the same configuration as the MOS transistor 321 is also provided in the semiconductor substrate 76. Further, the MOS transistor 324 of the NAND circuit 281 of the drive circuit 63 having substantially the same configuration as the MOS transistor 323 is also provided in the semiconductor substrate 76. The resistor 51b of the level-shift circuit 62 having substantially the same configuration as the resistor 51a is further provided on the semiconductor substrate 76.

A drain region 77a of p⁺-type and a source region 77b of p⁺-type, which are elements included in the MOS transistor 321, are provided separately from each other at the upper part of the semiconductor substrate 76. A gate electrode 82d is deposited on a part of the top surface side of the semiconductor substrate 76 with the gate insulating film 81d interposed across the drain region 77a and the source region 77b. The drain region 77a and the source region 77b are formed by ion implantation by use of the gate insulating film 81d and the gate electrode 82d as a mask.

A well region 78 of p-type, which is an element included in the MOS transistor 323 of the drive circuit 63, is provided at the upper part of the semiconductor substrate 76. A drain region 79a of n⁺-type and a source region 79b of n⁺-type are provided separately from each other at the upper part of the p-type well region 78. A gate electrode 82e is deposited on a part of the top surface side of the p-type well region 78 with the gate insulating film 81e interposed across the drain region 79a and the source region 79b. The drain region 79a and the source region 79b are formed by ion implantation by use of the gate insulating film 81e and the gate electrode 82e as a mask.

The resistor 51a of the level-shift circuit 62 is provided on the top surface side of the semiconductor substrate 76. While FIG. 12 indicates the resistor 51a by the circuit symbol, an insulating film may be formed on the top surface of the semiconductor substrate 76, and a polysilicon film having resistivity may be further formed on the top surface of the insulating film so as to provide the resistor 51a of the polysilicon film, for example. On end of the resistor 51a may be connected to the terminal VB via an aluminum-silicon (AlSi) layer, and the other end may be connected to the drain region 74d of the MOS transistor 52a provided in the semiconductor substrate 71 via a bonding wire.

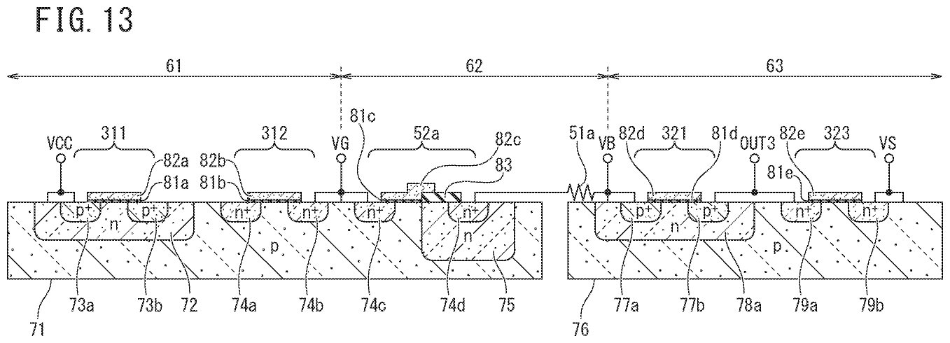

FIG. 13 is a cross-sectional view illustrating another example of the structure of the main part of the semiconductor device 31, which is a first modified example of the first embodiment. The semiconductor device 31 illustrated in FIG. 13 differs from the semiconductor device 31 illustrated in FIG. 12 in that the semiconductor substrate 76 provided toward the drive circuit 63 is not the n-type but the p-type. A well region 78a of n-type is provided at the upper part of the semiconductor substrate 76. The p⁺-type drain region 77a and the p⁺-type drain region 77b of the MOS transistor 321 are provided separately from each other at the upper part of the n-type well region 78a. The n⁺-type drain region 79a and the n⁺-type drain region 79b of the MOS transistor 323 are provided separately from each other at the upper part of the semiconductor substrate 76. The other configurations of the semiconductor device 31 illustrated in FIG. 13 are substantially the same as those of the semiconductor device 31 illustrated in FIG. 12, and overlapping explanations are not repeated below.

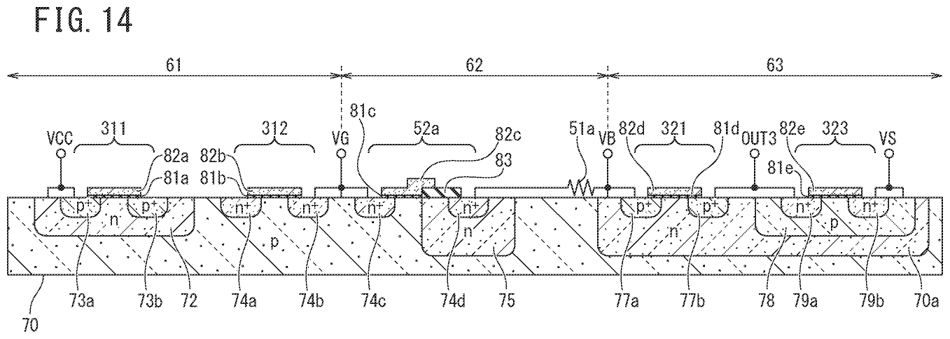

FIG. 14 is a view illustrating a cross-sectional structure of a main part of a semiconductor device of a comparative example. As illustrated in FIG. 14, the semiconductor device of the comparative example differs from the semiconductor device illustrated in FIG. 12 and FIG. 13 in that the upper-arm control circuit 61 and the drive circuit 63 are not independently provided in the upper-arm control circuit 61 or the drive circuit 63 but are integrated in a single p-type semiconductor substrate 70. The constitutional elements of the upper-arm control circuit 61 illustrated in FIG. 14 are the same as those of the upper-arm control circuit 61 illustrated in FIG. 12 and FIG. 13, and overlapping explanations are not repeated below.

The semiconductor device of the comparative example illustrated in FIG. 14 includes a well region 70a of n-type, as an element included in the respective MOS transistors 321 and 323 of the drive circuit 63, provided separately from the n-type high-voltage well region 75 at the upper part of the semiconductor substrate 70. The p⁺-type drain region 77a and the p⁺-type source region 77b of the MOS transistor 321 are provided separately from each other at the upper part of the n-type well region 70a. The gate electrode 82d of the MOS transistor 321 is deposited on a part of the top surface side of the n-type well region 70a with the gate insulating film 81d interposed across the drain region 77a and the source region 77b.

The p-type well region 78 is provided at the upper part of the n-type well region 70a. The n⁺-type drain region 79a and the n⁺-type source region 79b of the MOS transistor 323 are provided separately from each other at the upper part of the p-type well region 78. The gate electrode 82e of the MOS transistor 323 is deposited on a part of the top surface side of the p-type well region 78 with the gate insulating film 81e interposed across the drain region 79a and the source region 79b.

The configuration of the semiconductor device of the comparative example illustrated in FIG. 14, which includes the n-type well region 70a at the upper part of the p-type semiconductor substrate 70 and further includes the p-type well region 78 at the upper part of the n-type well region 70a, impedes a provision of a two-layered or three-layered high-breakdown-voltage diffusion structure.

In contrast, the configuration of the semiconductor device 31 according to the first embodiment illustrated in FIG. 12 and FIG. 13, which includes the semiconductor substrates 71 and 76 provided separately from each other and each independently provided with the upper-arm control circuit 61 and the drive circuit 63, does not need to have a two-layered or three-layered high-breakdown-voltage diffusion structure, so as to facilitate the manufacture of the device accordingly.

Further, the configuration according to the first embodiment can regulate the area used for the n-type high-voltage well region 75 around the drain region 74d of the MOS transistor 52a of the level-shift circuit 62, so as to avoid a leakage current and a parasitic operation caused in the high-breakdown-voltage part. Further, the decrease in width (circumferential length) of the n-type high-voltage well region 75 can lead to a decrease in area of the voltage blocking structure part, contributing to a reduction in chip cost accordingly.

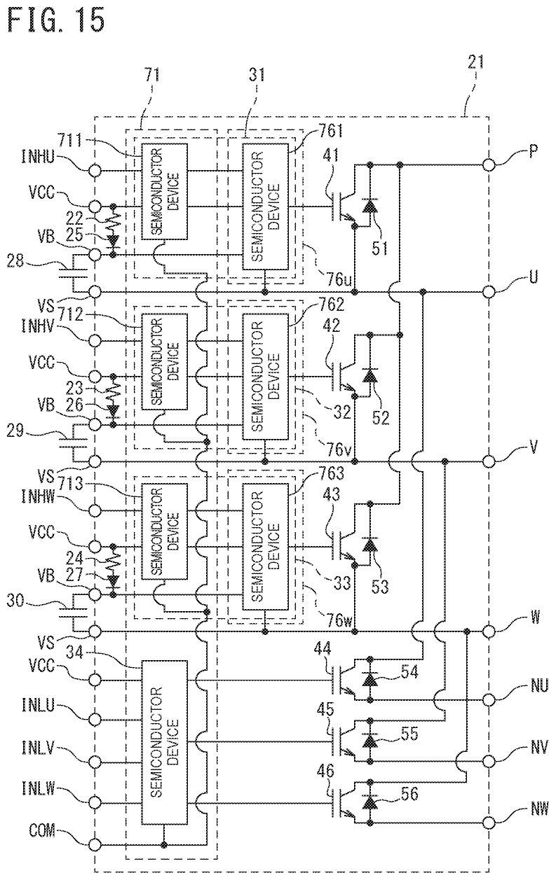

FIG. 15 is a diagram illustrating another example of the schematic configuration of the semiconductor device 21 as a second modified example of the first embodiment. The semiconductor device 21 illustrated in FIG. 15 differs from the semiconductor device 21 illustrated in FIG. 3 in internally including the resistors 22 to 24 and the diodes 25 to 27 and externally including the capacitors 28 to 30. One end of the respective capacitors 28 to 30 is connected to the terminal VB, and the other end is connected to the terminal VS. The semiconductor device 21 illustrated in FIG. 15 further differs from the semiconductor device 21 illustrated in FIG. 3 in that the semiconductor device 31 is implemented by divided semiconductor devices 711 and 761, the semiconductor device 32 is implemented by divided semiconductor devices 712 and 762, and the semiconductor device 33 is implemented by divided semiconductor devices 713 and 763. Alternatively, the semiconductor device 21 may include the resistors 22 to 24 and the diodes 25 to 27 not internally but externally, as in the case of the semiconductor device 21 illustrated in FIG. 3.

As indicated by the broken line in FIG. 15, the semiconductor devices 711, 712, and 713 and the lower-arm control circuit 34 are integrally provided in the semiconductor substrate 71. The semiconductor devices 711, 712, and 713 each include the upper-arm control circuit 61 and the MOS transistors 52a and 52b of the level-shift circuit 62 of the respective semiconductor devices 31 to 33. The semiconductor devices 711, 712, and 713 are provided respectively in the semiconductor substrates 76u, 76v, and 76w. The semiconductor devices 761, 762, and 763 each include the drive circuit 63 and the resistors 51a and 51b of the level-shift circuit 62 of the respective semiconductor devices 31 to 33. The respective semiconductor substrates 76u, 76v, and 76w have a structure corresponding to that of the semiconductor substrate 76 illustrated in FIG. 11 or FIG. 12.

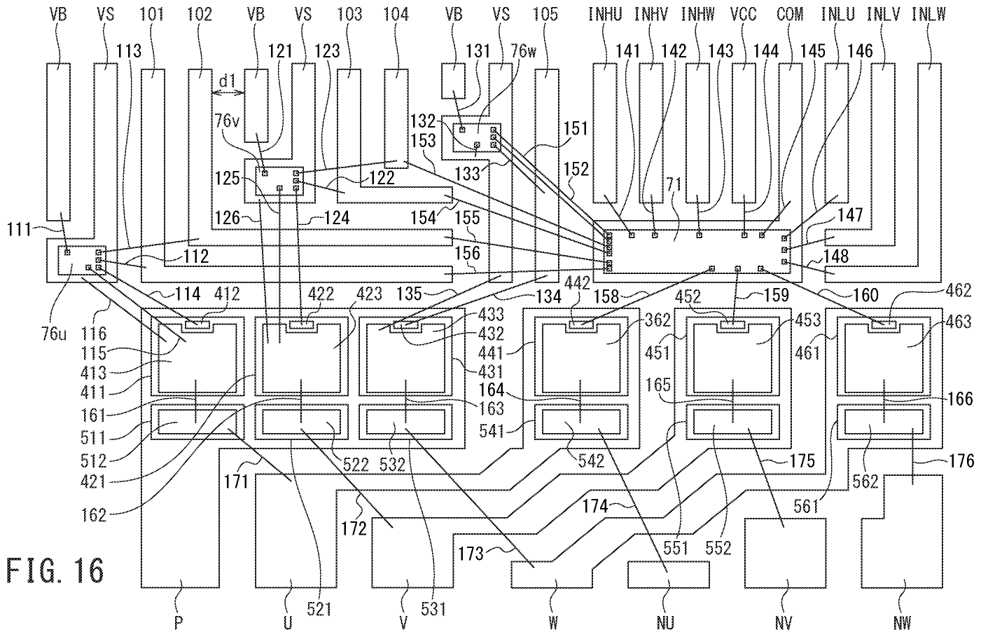

FIG. 16 is a view illustrating an example of a packaged configuration of the semiconductor device 10 according to the first embodiment. As illustrated in FIG. 16, the semiconductor device 10 according to the first embodiment includes the respective terminals VB of the U-phase, the V-phase, and the W-phase, the respective terminals VS of the U-phase, the V-phase, and the W-phase, and the terminals INHU, INHV, INHW, VCC, COM, INLU, INLV, INLW, P, U, V, W, NU, NV, and NW. The respective terminals VB of the U-phase, the V-phase, and the W-phase, the respective terminals VS of the U-phase, the V-phase, and the W-phase, and the terminals INHU, INHV, INHW, VCC, COM, INLU, INLV, INLW, P, U, V, W, NU, NV, and NW each include conductive material such as aluminum or copper, for example.

The respective terminals VB of the U-phase, the V-phase, and the W-phase, the respective terminals VS of the U-phase, the V-phase, and the W-phase, and the terminals INHU, INHV, INHW, VCC, COM, INLU, INLV, and INLW are provided on one of the sides (on the upper side in FIG. 16) of the semiconductor device 10 according to the first embodiment. The three terminals, the terminal VB of the U-phase, the terminal VB of the V-phase, and the terminal VB of the W-phase, are sequentially arranged from the left in FIG. 16. The three terminals, the terminal VS of the U-phase, the terminal VS of the V-phase, and the terminal VS of the W-phase, are sequentially arranged from the left in FIG. 16. The terminals P, U, V, W, NU, NV, and NW are arranged on the opposite side of the terminals INHU, INHV, INHW, VCC, COM, INLU, INLV, and INLW (on the lower side in FIG. 16).

The respective terminals VB of the U-phase, the V-phase, and the W-phase illustrated in FIG. 16 correspond to the respective terminals VB of the U-phase, the V-phase, and the W-phase illustrated in FIG. 15. The respective terminals VS of the U-phase, the V-phase, and the W-phase illustrated in FIG. 16 correspond to the respective terminals VS of the U-phase, the V-phase, and the W-phase illustrated in FIG. 3 or FIG. 15. The terminals INHU, INHV, INHW, and VCC illustrated in FIG. 16 correspond to the terminals INHU, INHV, INHW, and VCC illustrated in FIG. 3 or FIG. 15. The terminal COM illustrated in FIG. 16 corresponds to the terminal COM illustrated in FIG. 3 or FIG. 15. The terminals INLU, INLV, and INLW illustrated in FIG. 16 correspond to the terminals INLU, INLV, and INLW illustrated in FIG. 3 or FIG. 15. The terminal P illustrated in FIG. 16 corresponds to the terminal P illustrated in FIG. 3 or FIG. 15. The terminals U, V, and W illustrated in FIG. 16 correspond to the terminals U, V, and W illustrated in FIG. 3 or FIG. 15. The terminals NU, NV, and NW illustrated in FIG. 16 correspond to the terminals NU, NV, and NW illustrated in FIG. 3 or FIG. 15.

Relay wiring elements 101 and 102 are interposed between the terminal VS of the U-phase and the terminal VB of the V-phase. The relay wiring elements 101 and 102 each have an L-shaped planar pattern. The relay wiring element 102 and the terminal VB of the V-shape are separated from each other at a predetermined creepage distance d1. The relay wiring elements 101 and 102 each have a first straight part extending in one direction, which is the upper-lower direction in FIG. 16, and a second straight part extending in a direction perpendicular to the one direction, which is the right-left direction in FIG. 16. Relay wiring elements 103 and 104 are interposed between the terminal VS of the V-phase and the terminal VB of the W-phase. The relay wiring element 103 has an L-shaped planar pattern. The relay wiring element 103 has a first straight part extending in one direction (in the upper-lower direction in FIG. 16), and a second straight part extending in a direction perpendicular to the one direction (in the right-left direction in FIG. 16). The relay wiring element 104 has a straight planar pattern extending in one direction, which is the upper-lower direction in FIG. 16.

The semiconductor chips 411, 421, 431, 441, 451, and 461 illustrated in FIG. 16 are IGBT chips corresponding to the switching elements 41 to 46 of the semiconductor device 21 illustrated in FIG. 3 or FIG. 15. The semiconductor chips 511, 521, 531, 541, 551, and 561 illustrated in FIG. 16 are FWD chips corresponding to the FWDs 51 to 56 of the semiconductor device 21 illustrated in FIG. 3 or FIG. 15. Instead of the combination of the semiconductor chips 411, 421, 431, 441, 451, and 461 and the semiconductor chips 511, 521, 531, 541, 551, and 561, a reverse-conducting IGBT (RC-IGBT) may be used for the respective chips.

The semiconductor chip 71 illustrated in FIG. 16 corresponds to the semiconductor chip 71 illustrated in FIG. 15. The semiconductor chip 71 illustrated in FIG. 16 is provided with the semiconductor devices 711 to 713 and the lower-arm control circuit 34, which are integrated together. The semiconductor chip 71 illustrated in FIG. 16 may be divided into a plurality of semiconductor chips so that the respective semiconductor devices 711 to 713 and the lower-arm control circuit 34 are provided in each of the divided semiconductor chips. Alternatively, the semiconductor chip 71 illustrated in FIG. 16 may be divided into a plurality of semiconductor chips so as to provide circuits each including the upper-arm control circuit 61 of the respective semiconductor devices 711, 712, and 713 and the lower-arm control circuit 34 to implement the U-phase, the V-phase, and the W-phase.

The semiconductor chips 76u, 76v, and 76w illustrated in FIG. 16 each correspond to the semiconductor chip 76 of the respective semiconductor devices 31 to 33 illustrated in FIG. 12 or FIG. 13. The semiconductor chip 76u is provided with the semiconductor device 761. The semiconductor chip 76v is provided with the semiconductor device 762. The semiconductor chip 76w is provided with the semiconductor device 763.

The semiconductor chip 76u is arranged on the top surface side of the terminal VS of the U-phase. The semiconductor chip 76u is connected to the terminal VB of the U-phase via a wire 111. The semiconductor chip 76u is connected to the relay wiring element 101 via a wire 112. The relay wiring element 101 is connected to the semiconductor chip 71 via a wire 156. The semiconductor chip 76u is connected to the relay wiring element 102 via a wire 113. The relay wiring element 102 is connected to the semiconductor chip 71 via a wire 155. The semiconductor chip 76u is connected to a gate electrode 412 of the semiconductor chip 411 via a wire 114. The semiconductor chip 76u is connected to an emitter electrode 413 of the semiconductor chip 411 via a wire 115. The terminal VS of the U-phase is connected to the emitter electrode 413 of the semiconductor chip 411 via a wire 116.

The semiconductor chip 76v is arranged on the top surface side of the terminal VS of the V-phase. The semiconductor chip 76v is connected to the terminal VB of the V-phase via a wire 121. The semiconductor chip 76v is connected to the relay wiring element 103 via a wire 122. The relay wiring element 103 is connected to the semiconductor chip 71 via a wire 154. The semiconductor chip 76v is connected to the relay wiring element 104 via a wire 123. The relay wiring element 104 is connected to the semiconductor chip 71 via a wire 153. The semiconductor chip 76v is connected to a gate electrode 422 of the semiconductor chip 421 via a wire 124. The semiconductor chip 76v is connected to an emitter electrode 423 of the semiconductor chip 421 via a wire 125. The terminal VS of the V-phase is connected to the emitter electrode 423 of the semiconductor chip 421 via a wire 126.

The semiconductor chip 76w is arranged on the top surface side of the terminal VS of the W-phase. The semiconductor chip 76w is connected to the terminal VB of the W-phase via a wire 131. The semiconductor chip 76w is connected to the terminal VS of the W-phase via a wire 132. The terminal VS of the W-phase is connected to an emitter electrode 433 of the semiconductor chip 431 via a wire 135. The semiconductor chip 76w is connected to the relay wiring element 105 via a wire 133. The relay wiring element 105 is connected to a gate electrode 432 of the semiconductor chip 431 via a wire 134. The semiconductor chip 76w is connected to the semiconductor chip 71 via wires 151 and 152.

The semiconductor chip 71 is provided on the top surface side of the terminal COM. The semiconductor chip 71 is connected to the terminal INHU via a wire 141. The semiconductor chip 71 is connected to the terminal INHV via a wire 142. The semiconductor chip 71 is connected to the terminal INHW via a wire 143. The semiconductor chip 71 is connected to the terminal VCC via a wire 144. The semiconductor chip 71 is connected to the terminal COM via a wire 145. The semiconductor chip 71 is connected to the terminal INLU via a wire 146. The semiconductor chip 71 is connected to the terminal INLV via a wire 147. The semiconductor chip 71 is connected to the terminal INLW via a wire 148.

The semiconductor chip 71 is connected to a gate electrode 442 of the semiconductor chip 441 via a wire 158. The semiconductor chip 71 is connected to a gate electrode 452 of the semiconductor chip 451 via a wire 159. The semiconductor chip 71 is connected to a gate electrode 462 of the semiconductor chip 461 via a wire 160.

The semiconductor chips 411, 421, and 431 and the semiconductor chips 511, 521, and 531 are provided on the top surface side of the terminal P. A collector electrode on the rear surface side of the respective semiconductor chips 411, 421, and 431 and a cathode electrode on the rear surface side of the respective semiconductor chips 511, 521, and 531 are electrically connected to the terminal P.

The emitter electrode 413 of the semiconductor chip 411 is connected to an anode electrode 512 of the semiconductor chip 511 via a wire 161. The anode electrode 512 of the semiconductor chip 511 is connected to the terminal U via a wire 171. The emitter electrode 423 of the semiconductor chip 421 is connected to an anode electrode 522 of the semiconductor chip 521 via a wire 162. The anode electrode 522 of the semiconductor chip 521 is connected to the terminal V via a wire 172. The emitter electrode 433 of the semiconductor chip 431 is connected to an anode electrode 532 of the semiconductor chip 531 via a wire 163. The anode electrode 532 of the semiconductor chip 531 is connected to the terminal W via a wire 173.

The semiconductor chip 441 and the semiconductor chip 541 are provided on the top surface side of the terminal U. A collector electrode on the rear surface side of the semiconductor chip 441 and a cathode electrode on the rear surface side of the semiconductor chip 541 are electrically connected to the terminal U. An emitter electrode 443 of the semiconductor chip 441 is connected to an anode electrode 542 of the semiconductor chip 541 via a wire 164. An anode electrode 542 of the semiconductor chip 541 is connected to the terminal NU via a wire 174.

The semiconductor chip 451 and the semiconductor chip 551 are provided on the top surface side of the terminal V. A collector electrode on the rear surface side of the semiconductor chip 451 and a cathode electrode on the rear surface side of the semiconductor chip 551 are electrically connected to the terminal V. An emitter electrode 453 of the semiconductor chip 451 is connected to an anode electrode 552 of the semiconductor chip 551 via a wire 165. An anode electrode 552 of the semiconductor chip 551 is connected to the terminal NV via a wire 175.

The semiconductor chip 461 and the semiconductor chip 561 are provided on the top surface side of the terminal W. A collector electrode on the rear surface side of the semiconductor chip 461 and a cathode electrode on the rear surface side of the semiconductor chip 561 are electrically connected to the terminal W. An emitter electrode 463 of the semiconductor chip 461 is connected to an anode electrode 562 of the semiconductor chip 561 via a wire 166. An anode electrode 562 of the semiconductor chip 561 is connected to the terminal NW via a wire 176.

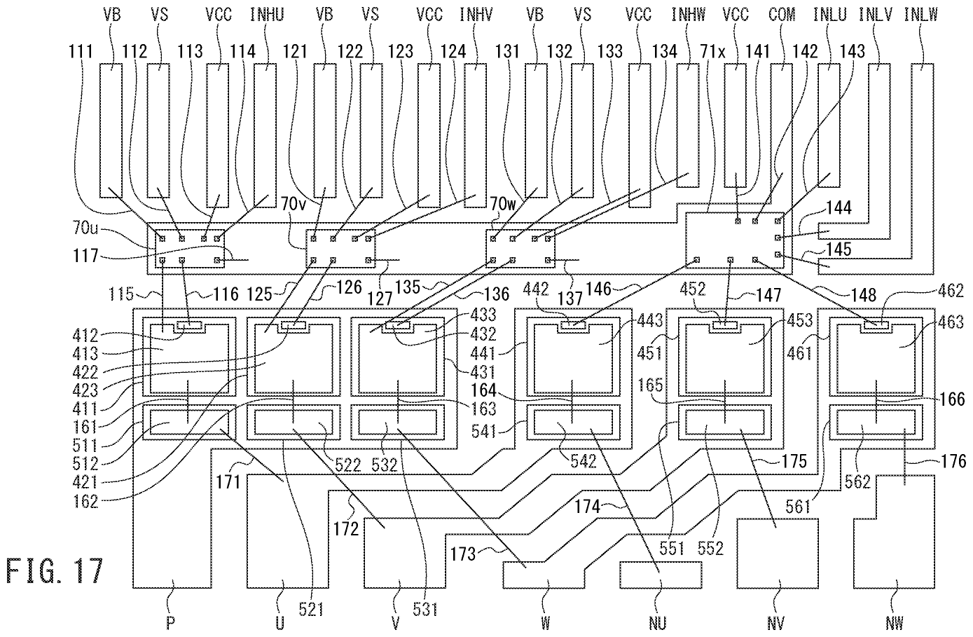

FIG. 17 is a view illustrating a packaged configuration of the semiconductor device of the comparative example. As illustrated in FIG. 17, the semiconductor device of the comparative example includes the respective terminals VB of the U-phase, the V-phase, and the W-phase, the respective terminals VS of the U-phase, the V-phase, and the W-phase, the respective terminals VCC of the U-phase, the V-phase, and the W-phase, and the terminals INHU, INHV, INHW, VCC, COM, INLU, INLV, INLW, P, U, V, W, NU, NV, and NW.

The semiconductor device of the comparative example includes the semiconductor chips 70u, 70v, 70w, 71x, 411, 421, 431, 441, 451, 461, 511, 521, 531, 541, 551, and 561. The semiconductor chips 411, 421, 431, 441, 451, 461, 511, 521, 531, 541, 551, and 561 are substantially the same as the semiconductor chips 411, 421, 431, 441, 451, 461, 511, 521, 531, 541, 551, and 561 illustrated in FIG. 16.

The lower-arm control circuit 34 is provided integrally in the semiconductor chip 71x illustrated in FIG. 17. Th semiconductor chips 70u, 70v, and 70w illustrated in FIG. 17 each correspond to the semiconductor substrate 70 of the respective semiconductor devices 31 to 33 illustrated in FIG. 14. The upper-arm control circuit 61, the level-shift circuit 62, and the drive circuit 63 of the semiconductor chip 31 are integrated together in the semiconductor chip 70u illustrated in FIG. 17. The upper-arm control circuit 61, the level-shift circuit 62, and the drive circuit 63 of the semiconductor chip 32 are integrated together in the semiconductor chip 70v illustrated in FIG. 17. The upper-arm control circuit 61, the level-shift circuit 62, and the drive circuit 63 of the semiconductor chip 33 are integrated together in the semiconductor chip 70w illustrated in FIG. 17.

The semiconductor chips 70u, 70v, 70w, and 71x are provided on the top surface side of the terminal COM. The semiconductor chip 70u is connected to the terminal VB of the U-phase via the wire 111. The semiconductor chip 70u is connected to the terminal VS of the U-phase via the wire 112. The semiconductor chip 70u is connected to the terminal VCC of the U-phase via the wire 113. The semiconductor chip 70u is connected to the terminal INHU of the U-phase via the wire 114. The semiconductor chip 70u is connected to the emitter electrode 413 of the semiconductor chip 411 via the wire 115. The semiconductor chip 70u is connected to the gate electrode 412 of the semiconductor chip 411 via the wire 116.

The semiconductor chip 70v is connected to the terminal VB of the V-phase via the wire 121. The semiconductor chip 70v is connected to the terminal VS of the V-phase via the wire 122. The semiconductor chip 70v is connected to the terminal VCC of the V-phase via the wire 123. The semiconductor chip 70v is connected to the terminal INHV via the wire 124. The semiconductor chip 70v is connected to the emitter electrode 423 of the semiconductor chip 421 via the wire 125. The semiconductor chip 70v is connected to the gate electrode 422 of the semiconductor chip 421 via the wire 126.

The semiconductor chip 70w is connected to the terminal VB of the W-phase via the wire 131. The semiconductor chip 70w is connected to the terminal VS of the W-phase via the wire 132. The semiconductor chip 70w is connected to the terminal VCC of the W-phase via the wire 133. The semiconductor chip 70w is connected to the terminal INHW via the wire 134. The semiconductor chip 70w is connected to the emitter electrode 433 of the semiconductor chip 431 via the wire 135. The semiconductor chip 70w is connected to the gate electrode 432 of the semiconductor chip 431 via the wire 136.

The semiconductor chip 71x is connected to the terminal VCC via the wire 141. The semiconductor chip 71x is connected to the terminal COM via the wire 142. The semiconductor chip 71x is connected to the terminal INLU via the wire 143. The semiconductor chip 71x is connected to the terminal INLV via the wire 144. The semiconductor chip 71x is connected to the terminal INLW via the wire 145. The semiconductor chip 71x is connected to the gate electrode 442 of the semiconductor chip 441 via the wire 146. The semiconductor chip 71x is connected to the gate electrode 452 of the semiconductor chip 451 via the wire 147. The semiconductor chip 71x is connected to the gate electrode 462 of the semiconductor chip 461 via the wire 148.

The relation of the connection between the respective semiconductor chips 411, 421, 431, 441, 451, 461, 511, 521, 531, 541, 551, and 561 illustrated in FIG. 17 is substantially the same as that between the respective semiconductor chips 411, 421, 431, 441, 451, 461, 511, 521, 531, 541, 551, and 561 illustrated in FIG. 16, and overlapping explanations are not repeated below.

The semiconductor device 10 according to the first embodiment has the configuration in which the upper-arm control circuit 61 and the drive circuit 63 are provided on the different substrates independently of each other, so as to decrease a leakage current during a standby state regardless of whether the power-supply potential Vp of the power source 14 is large. Further, the decrease in the area of the high-breakdown-voltage part can contribute to a decrease in circuit area.

### Second Embodiment

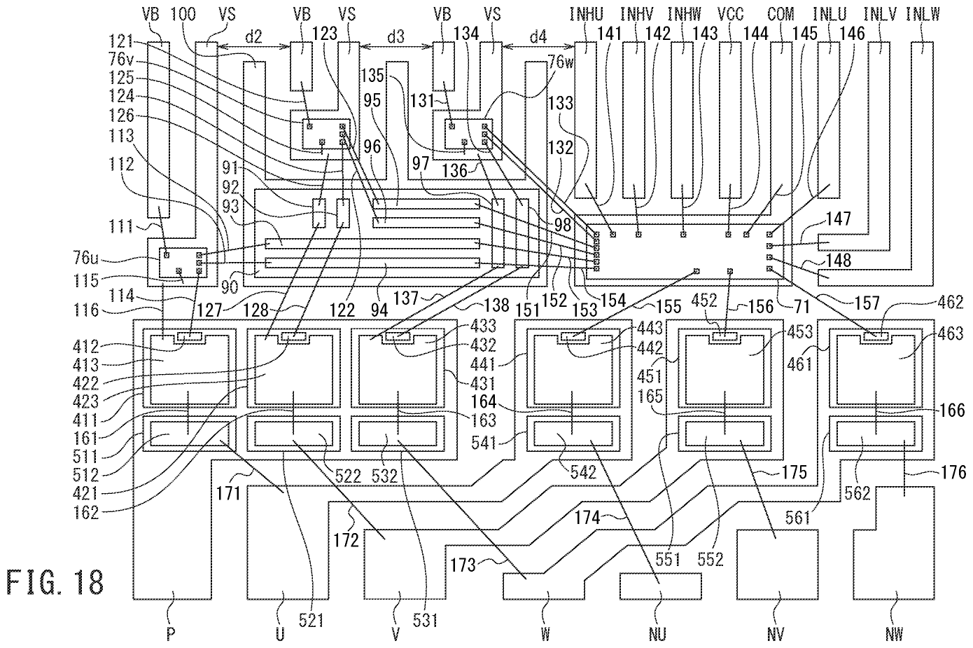

FIG. 18 is a view illustrating an example of a packaged configuration of a semiconductor device according to a second embodiment. As illustrated in FIG. 18, the semiconductor device according to the second embodiment differs from the semiconductor device according to the first embodiment illustrated in FIG. 14 in further including a wired substrate including an insulating substrate 90 and relay wiring elements 91 to 98 provided on a top surface side of a substrate-supporting frame 100.

The semiconductor device according to the second embodiment includes the respective terminals VB of the U-phase, the V-phase, and the W-phase, the respective terminals VS of the U-phase, the V-phase, and the W-phase, and the terminals INHU, INHV, INHW, VCC, COM, INLU, INLV, INLW, P, U, V, W, NU, NV, and NW.

The substrate-supporting frame 100 includes conductive material such as aluminum or copper, for example. The substrate-supporting frame 100 may include the same material as the terminals INHU, INHV, INHW, VCC, COM, INLU, INLV, INLW, P, U, V, W, NU, NV, and NW.

The substrate-supporting frame 100 has a comb-shaped planar pattern. One of the teeth of the comb-shaped member of the substrate-supporting frame 100 is located between the terminal VS of the U-phase and the terminal VB of the V-phase. Another one of the teeth of the comb-shaped member of the substrate-supporting frame 100 is located between the terminal VS of the V-phase and the terminal VB of the W-phase. Still another one of the teeth of the comb-shaped member of the substrate-supporting frame 100 is located between the terminal VS of the W-phase and the terminal INHU.

The insulating substrate 90 is provided on the top surface side of the handle part of the comb-shaped member of the substrate-supporting frame 100. The insulating substrate 90 is bonded to the substrate-supporting frame 100 with insulating tape, for example. The insulating substrate 90 includes insulation material such as alumina. The relay wiring elements (printed wiring elements) 91 to 98 are provided on the top surface side of the insulating substrate 90. The insulating substrate 90 and the relay wiring elements 91 to 98 implement the wired substrate. The relay wiring elements 91, 92, 97, and 98 are provided separately from each other and each have a straight planar pattern extending parallel to each other in one direction (in the upper-lower direction in FIG. 18). The relay wiring elements 93 to 96 are provided separately from each other and each have a straight planar pattern extending parallel to each other in a direction perpendicular to the one direction (in the right-left direction in FIG. 18).

The semiconductor device according to the second embodiment includes the semiconductor chips 411, 421, 431, 441, 451, 461, 511, 521, 531, 541, 551, 561, 71, 76u, 76v, and 76w. The semiconductor chips 411, 421, 431, 441, 451, 461, 511, 521, 531, 541, 551, 561, 71, 76u, 76v, and 76w illustrated in FIG. 18 have substantially the same configuration as those illustrated in FIG. 16, and overlapping explanations are not repeated below.

The semiconductor chip 76u is arranged on the top surface side of the terminal VS of the U-phase. The semiconductor chip 76u is connected to the terminal VB of the U-phase via the wire 111. The semiconductor chip 76u is connected to the relay wiring element 94 via the wire 112. The relay wiring element 94 is connected to the semiconductor chip 71 via the wire 154. The semiconductor chip 76u is connected to the relay wiring element 93 via the wire 113. The relay wiring element 93 is connected to the semiconductor chip 71 via the wire 153. The semiconductor chip 76u is connected to the gate electrode 412 of the semiconductor chip 411 via the wire 114. The semiconductor chip 76u is connected to the terminal VS of the U-phase via the wire 115. The terminal VS of the U-phase is connected to the emitter electrode 413 of the semiconductor chip 411 via the wire 116.

The semiconductor chip 76v is arranged on the top surface side of the terminal VS of the V-phase. The semiconductor chip 76v is connected to the terminal VB of the V-phase via the wire 121. The semiconductor chip 76v is connected to the relay wiring element 96 via the wire 122. The relay wiring element 96 is connected to the semiconductor chip 71 via the wire 152. The semiconductor chip 76v is connected to the relay wiring element 95 via the wire 123. The relay wiring element 95 is connected to the semiconductor chip 71 via the wire 151. The semiconductor chip 76v is connected to the relay wiring element 92 via the wire 124. The relay wiring element 92 is connected to the gate electrode 422 of the semiconductor chip 421 via the wire 128. The semiconductor chip 76v is connected to the terminal VS of the V-phase via the wire 125. The terminal VS of the V-phase is connected to the relay wiring element 91 via the wire 126. The relay wiring element 91 is connected to the emitter electrode 423 of the semiconductor chip 421 via the wire 127.

The semiconductor chip 76w is arranged on the top surface side of the terminal VS of the W-phase. The semiconductor chip 76w is connected to the terminal VB of the W-phase via the wire 131. The semiconductor chip 76w is connected to the semiconductor chip 71 via the wires 132 and 133. The semiconductor chip 76w is connected to the relay wiring element 98 via the wire 134. The relay wiring element 98 is connected to the gate electrode 432 of the semiconductor chip 431 via the wire 138. The semiconductor chip 76w is connected to the terminal VS of the W-phase via the wire 135. The terminal VS of the W-phase is connected to the relay wiring element 97 via the wire 136. The relay wiring element 97 is connected to the emitter electrode 433 of the semiconductor chip 431 via the wire 137.

The semiconductor chip 71 is provided on the top surface side of the terminal COM. The semiconductor chip 71 is connected to the terminal INHU via the wire 141. The semiconductor chip 71 is connected to the terminal INHV via the wire 142. The semiconductor chip 71 is connected to the terminal INHW via the wire 143. The semiconductor chip 71 is connected to the terminal VCC via the wire 144. The semiconductor chip 71 is connected to the terminal COM via the wire 145. The semiconductor chip 71 is connected to the terminal INLU via the wire 146. The semiconductor chip 71 is connected to the terminal INLV via the wire 147. The semiconductor chip 71 is connected to the terminal INLW via the wire 148.

The semiconductor chip 71 is connected to the gate electrode 442 of the semiconductor chip 441 via the wire 155. The semiconductor chip 71 is connected to the gate electrode 452 of the semiconductor chip 451 via the wire 156. The semiconductor chip 71 is connected to the gate electrode 462 of the semiconductor chip 461 via the wire 157.

The relation of the connection between the respective semiconductor chips 411, 421, 431, 441, 451, 461, 511, 521, 531, 541, 551, and 561 illustrated in FIG. 18 is substantially the same as that between the respective semiconductor chips 411, 421, 431, 441, 451, 461, 511, 521, 531, 541, 551, and 561 illustrated in FIG. 16, and overlapping explanations are not repeated below. The other configurations of the semiconductor device according to the second embodiment are substantially the same as those of the semiconductor device according to the first embodiment, and overlapping explanations are not repeated below.

The semiconductor device according to the second embodiment has the configuration in which the upper-arm control circuit 61 and the drive circuit 63 are provided on the different substrates independently of each other, as in the case of the semiconductor device according to the first embodiment, so as to decrease a leakage current during a standby state regardless of whether the power-supply potential Vp of the power source 14 is large. Further, the decrease in the area of the high-breakdown-voltage part can contribute to a decrease in circuit area.

### Third Embodiment

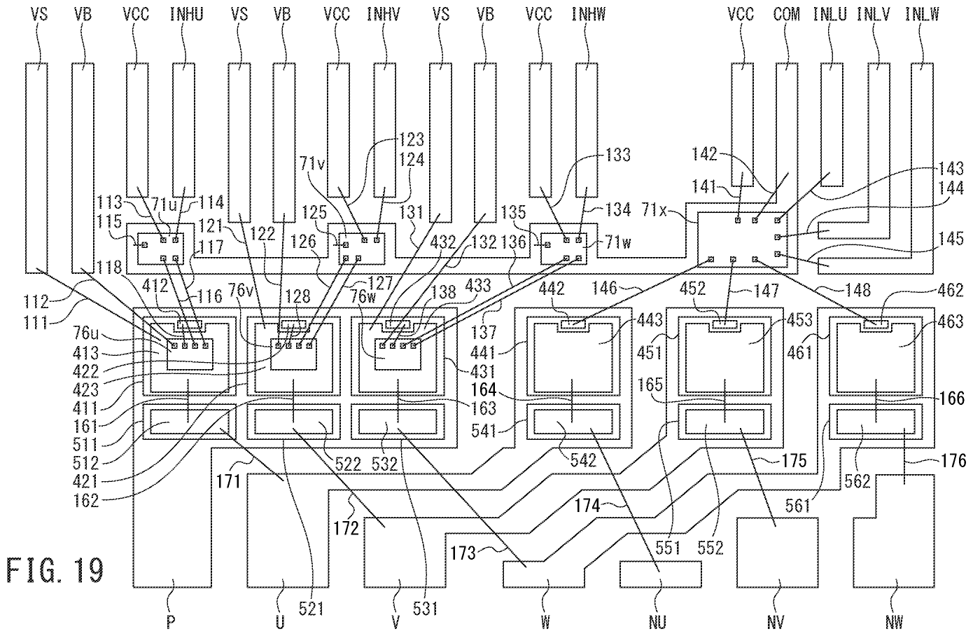

FIG. 19 is a view illustrating an example of a packaged configuration of a semiconductor device according to a third embodiment. As illustrated in FIG. 19, the semiconductor device according to the third embodiment differs from the semiconductor device according to the first embodiment illustrated in FIG. 16 in that the semiconductor chips 71u, 71v, and 71w provided with the semiconductor devices 711, 712, and 713 respectively are separated from the semiconductor chip 71x provided with the lower-arm control circuit 34, and in that the respective semiconductor chips 76u, 76v, and 76w are provided on the top surface sides of the respective semiconductor chips 411, 421, and 431 so as to implement a Chip-on-Chip (CoC) configuration.

The semiconductor device according to the third embodiment includes the respective terminals VB of the U-phase, the V-phase, and the W-phase, the respective terminals VS of the U-phase, the V-phase, and the W-phase, the respective terminals VCC of the U-phase, the V-phase, and the W-phase, and the terminals INHU, INHV, INHW, VCC, COM, INLU, INLV, INLW, P, U, V, W, NU, NV, and NW. The terminal COM has an L-shaped planar pattern. The terminal COM is provided to extend across the respective terminals VB of the V-phase and the W-phase, the respective terminals VS of the V-phase and the W-phase, the respective terminals VCC of the U-phase, the V-phase, and the W-phase, the terminals INHU, INHV, INHW, and VCC, and the semiconductor chips 411, 421, 431, 441, and 451.

The semiconductor device according to the third embodiment includes the semiconductor chips 411, 421, 431, 441, 451, 461, 511, 521, 531, 541, 551, 561, 71x, 71u, 71v, 71w, 76u, 76v, and 76w. The semiconductor chips 411, 421, 431, 441, 451, 461, 511, 521, 531, 541, 551, and 561 have substantially the same configuration as those illustrated in FIG. 16, and overlapping explanations are not repeated below.

The semiconductor chips 71x, 71u, 71v, and 71w are provided on the top surface side of the terminal COM. The semiconductor chip 71x is provided with the lower-arm control circuit 34. The semiconductor chip 71u is provided with the semiconductor device 711. The semiconductor chip 71v is provided with the semiconductor device 712. The semiconductor chip 71w is provided with the semiconductor device 713.

The semiconductor chips 76u, 76v, and 76w are provided on the top surface sides of the corresponding semiconductor chips 411, 421, and 431 so as to implement the Chip-on-Chip (CoC) configuration. The respective rear surfaces of the semiconductor chips 76u, 76v, and 76w are bonded to the top surfaces of the semiconductor chips 411, 421, and 431 with insulating tape, for example. The rear surfaces of the semiconductor chips 76u, 76v, and 76w may be electrically connected to the emitter electrodes 413, 423, and 433 of the semiconductor chips 411, 421, and 431.

The semiconductor chip 76u is provided with the semiconductor device 761. The semiconductor chip 76v is provided with the semiconductor device 762. The semiconductor chip 76w is provided with the semiconductor device 763.

The terminal VS of the U-phase is connected to the emitter electrode 413 of the semiconductor chip 411 via the wire 111. The terminal VB of the U-phase is connected to the semiconductor chip 76u via the wire 112. The semiconductor chip 71u is connected to the terminal VCC of the U-phase via the wire 113. The semiconductor chip 71u is connected to the terminal INHU via the wire 114. The semiconductor chip 71u is connected to the terminal COM via the wire 115. The semiconductor chip 71u is connected to the semiconductor chip 76u via the wires 116 and 117. The semiconductor chip 76u is connected to the gate electrode 412 of the semiconductor chip 411 via the wire 118.

The terminal VS of the V-phase is connected to the emitter electrode 423 of the semiconductor chip 421 via the wire 121. The terminal VB of the V-phase is connected to the semiconductor chip 76v via the wire 122. The semiconductor chip 71v is connected to the terminal VCC of the V-phase via the wire 123. The semiconductor chip 71v is connected to the terminal INHV via the wire 124. The semiconductor chip 71v is connected to the terminal COM via the wire 125. The semiconductor chip 71v is connected to the semiconductor chip 76v via the wires 126 and 127. The semiconductor chip 76v is connected to the gate electrode 422 of the semiconductor chip 421 via the wire 128.

The semiconductor chip 71x is connected to the terminal VCC via the wire 141. The semiconductor chip 71x is connected to the terminal COM via the wire 142. The semiconductor chip 71x is connected to the terminal INLU via the wire 143. The semiconductor chip 71x is connected to the terminal INLV via the wire 144. The semiconductor chip 71x is connected to the terminal INLW via the wire 145. The semiconductor chip 71x is connected to the gate electrode 442 of the semiconductor chip 441 via the wire 146. The semiconductor chip 71x is connected to the gate electrode 452 of the semiconductor chip 451 via the wire 147. The semiconductor chip 71x is connected to the gate electrode 462 of the semiconductor chip 461 via the wire 148.

The relation of the connection between the respective semiconductor chips 411, 421, 431, 441, 451, 461, 511, 521, 531, 541, 551, and 561 illustrated in FIG. 19 is substantially the same as that between the respective semiconductor chips 411, 421, 431, 441, 451, 461, 511, 521, 531, 541, 551, and 561 illustrated in FIG. 16, and overlapping explanations are not repeated below. The other configurations of the semiconductor device according to the third embodiment are substantially the same as those of the semiconductor device according to the first embodiment, and overlapping explanations are not repeated below.

The semiconductor device according to the third embodiment has the configuration in which the upper-arm control circuit 61 and the drive circuit 63 are provided on the different substrates independently of each other, as in the case of the semiconductor device according to the first embodiment, so as to decrease a leakage current during a standby state regardless of whether the power-supply potential Vp of the power source 14 is large. In addition, the decrease in the area of the high-breakdown-voltage part can contribute to a decrease in circuit area. Further, the configuration, in which the respective semiconductor chips 76u, 76v, and 76w provided with the drive circuit 63 are provided on the top surfaces of the corresponding semiconductor chips 411, 421, and 431 so as to implement the Chip-on-Chip (CoC) structure, does not need to ensure insulation between the respective chips because the substrate potential of the drive circuit 63 when set to the VS potential is equal to the chip-surface potential of the semiconductor chips 411, 421, and 431 of the respective switching element 41 to 43, so as to achieve a decrease in the packaged area accordingly.

### Fourth Embodiment

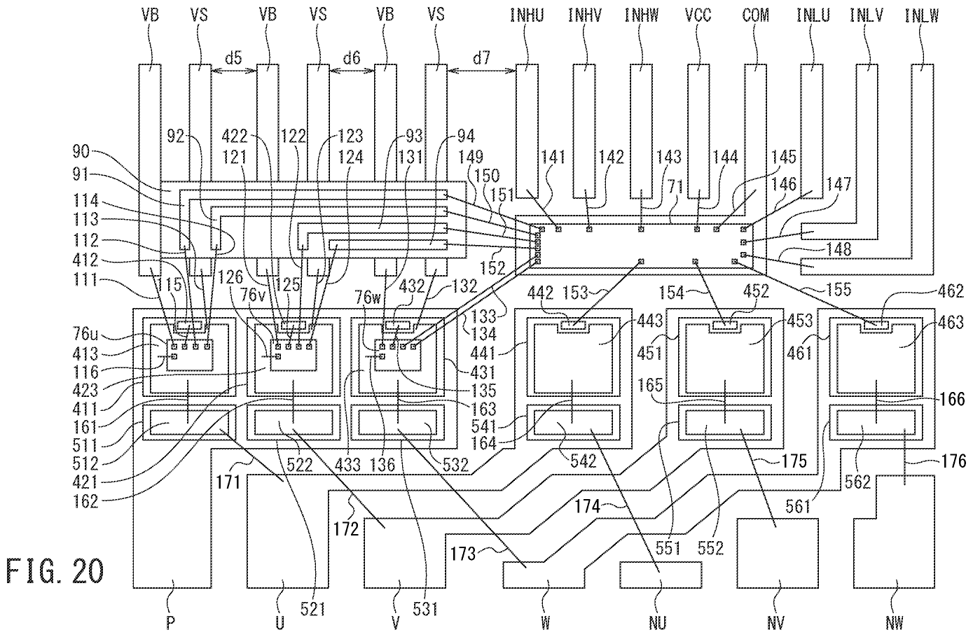

FIG. 20 is a view illustrating an example of a packaged configuration of a semiconductor device according to a fourth embodiment. As illustrated in FIG. 20, the semiconductor device according to the fourth embodiment differs from the semiconductor device according to the first embodiment illustrated in FIG. 16 in including a wired substrate including the insulating substrate 90 and the relay wiring elements 91 to 94, and further in that the respective semiconductor chips 76u, 76v, and 76w and the respective semiconductor chips 411, 421, and 431 implement a Chip-on-Chip (CoC) configuration.

The semiconductor device according to the fourth embodiment includes the respective terminals VB of the U-phase, the V-phase, and the W-phase, the respective terminals VS of the U-phase, the V-phase, and the W-phase, and the terminals INHU, INHV, INHW, VCC, COM, INLU, INLV, INLW, P, U, V, W, NU, NV, and NW.

The insulating substrate 90 is provided on the top surface side of each of the terminal VS of the U-phase, the terminals VB and VS of the V-phase, and the terminals VB and VS of the W-phase. The insulating substrate 90 is bonded to the terminal VS of the U-phase, the terminals VB and VS of the V-phase, and the terminals VB and VS of the W-phase with insulating tape, for example. The insulating substrate 90 includes insulation material such as alumina. The relay wiring elements (printed wiring elements) 91 to 94 are provided on the top surface side of the insulating substrate 90. The insulating substrate 90 and the relay wiring elements 91 to 94 implement the wired substrate. The relay wiring elements 91 to 93 each have an L-shaped planar pattern having a first straight part extending in one direction (in the upper-lower direction in FIG. 20) and a second straight part extending in a direction perpendicular to the one direction (in the right-left direction in FIG. 20). The relay wiring element 94 has a straight planar pattern extending in the direction perpendicular to the one direction (in the right-left direction in FIG. 20).

The semiconductor device according to the fourth embodiment includes the semiconductor chips 411, 421, 431, 441, 451, 461, 511, 521, 531, 541, 551, 561, 71, 76u, 76v, and 76w. The semiconductor chips 411, 421, 431, 441, 451, 461, 511, 521, 531, 541, 551, 561, 71, 76u, 76v, and 76w have substantially the same configuration as those illustrated in FIG. 16, and overlapping explanations are not repeated below.

The semiconductor chip 71 is provided on the top surface side of the terminal COM. The semiconductor chips 76u, 76v, and 76w are provided on the respective top surfaces of the semiconductor chips 411, 421, and 431 so as to implement the CoC configuration.

The terminal VB of the U-phase is connected to the semiconductor chip 76u via the wire 111. One end of the relay wiring element 91 is connected to the semiconductor chip 76u via the wire 112, and the other end is connected to the semiconductor chip 71 via the wire 149. One end of the relay wiring element 92 is connected to the semiconductor chip 76u via the wire 114, and the other end is connected to the semiconductor chip 71 via the wire 150. The terminal VS of the U-phase is connected to the emitter electrode 413 of the semiconductor chip 411 via the wire 113. The semiconductor chip 76u is connected to the gate electrode 412 of the semiconductor chip 411 via the wire 115. The semiconductor chip 76u is connected to the emitter electrode 413 of the semiconductor chip 411 via the wire 116.

The terminal VB of the V-phase is connected to the semiconductor chip 76v via the wire 121. One end of the relay wiring element 93 is connected to the semiconductor chip 76v via the wire 122, and the other end is connected to the semiconductor chip 71 via the wire 151. One end of the relay wiring element 94 is connected to the semiconductor chip 76v via the wire 124, and the other end is connected to the semiconductor chip 71 via the wire 152. The terminal VS of the V-phase is connected to the emitter electrode 423 of the semiconductor chip 421 via the wire 123. The semiconductor chip 76v is connected to the gate electrode 422 of the semiconductor chip 421 via the wire 125. The semiconductor chip 76v is connected to the emitter electrode 423 of the semiconductor chip 421 via the wire 126.

The terminal VB of the W-phase is connected to the semiconductor chip 76w via the wire 131. The terminal VS of the W-phase is connected to the emitter electrode 433 of the semiconductor chip 431 via the wire 132. The semiconductor chip 71 is connected to the semiconductor chip 76w via the wires 133 and 134. The semiconductor chip 76w is connected to the gate electrode 432 of the semiconductor chip 431 via the wire 135. The semiconductor chip 76w is connected to the emitter electrode 433 of the semiconductor chip 431 via the wire 136.

The semiconductor chip 71 is connected to the terminal INHU via the wire 141. The semiconductor chip 71 is connected to the terminal INHV via the wire 142. The semiconductor chip 71 is connected to the terminal INHW via the wire 143. The semiconductor chip 71 is connected to the terminal VCC via the wire 144. The semiconductor chip 71 is connected to the terminal COM via the wire 145. The semiconductor chip 71 is connected to the terminal INLU via the wire 146. The semiconductor chip 71 is connected to the terminal INLV via the wire 147. The semiconductor chip 71 is connected to the terminal INLW via the wire 148.

The semiconductor chip 71 is connected to the gate electrode 442 of the semiconductor chip 441 via the wire 153. The semiconductor chip 71 is connected to the gate electrode 452 of the semiconductor chip 451 via the wire 154. The semiconductor chip 71 is connected to the gate electrode 462 of the semiconductor chip 461 via the wire 155.

The relation of the connection between the respective semiconductor chips 411, 421, 431, 441, 451, 461, 511, 521, 531, 541, 551, and 561 illustrated in FIG. 20 is substantially the same as that between the respective semiconductor chips 411, 421, 431, 441, 451, 461, 511, 521, 531, 541, 551, and 561 illustrated in FIG. 16, and overlapping explanations are not repeated below. The other configurations of the semiconductor device according to the fourth embodiment are substantially the same as those of the semiconductor device according to the first embodiment, and overlapping explanations are not repeated below.

The semiconductor device according to the fourth embodiment has the configuration in which the upper-arm control circuit 61 and the drive circuit 63 are provided on the different substrates independently of each other, as in the case of the semiconductor device according to the first embodiment, so as to decrease a leakage current during a standby state regardless of whether the power-supply potential Vp of the power source 14 is large. In addition, the decrease in the area of the high-breakdown-voltage part can contribute to a decrease in circuit area. Further, the Chip-on-Chip (CoC) configuration can decrease the packaged area.

### Fifth Embodiment

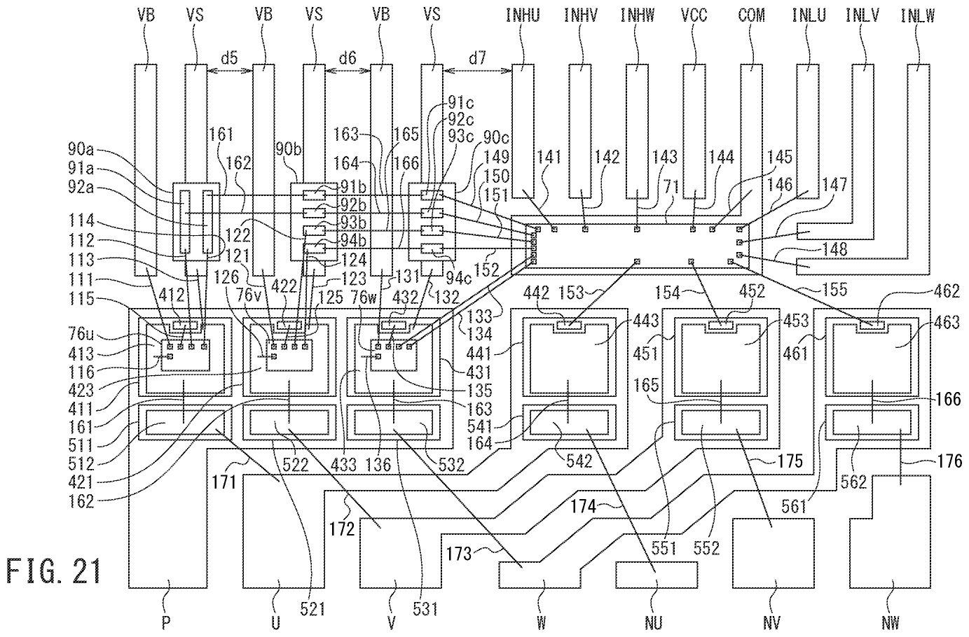

FIG. 21 is a view illustrating an example of a packaged configuration of a semiconductor device according to a fifth embodiment. As illustrated in FIG. 21, the semiconductor device according to the fifth embodiment differs from the semiconductor device according to the fourth embodiment illustrated in FIG. 20 in that the insulating substrate 90 is divided into three insulating substrates 90a, 90b, and 90c separated from each other.

The semiconductor device according to the fifth embodiment includes the respective terminals VB of the U-phase, the V-phase, and the W-phase, the respective terminals VS of the U-phase, the V-phase, and the W-phase, and the terminals INHU, INHV, INHW, VCC, COM, INLU, INLV, INLW, P, U, V, W, NU, NV, and NW, as illustrated in FIG. 21.

The insulating substrate 90a is provided on the top surface side of the terminal VS of the U-phase. The insulating substrate 90a is bonded to the terminal VS of the U-phase with insulating tape, for example. The insulating substrate 90a includes insulation material such as alumina. The relay wiring elements (printed wiring elements) 91a and 92a are provided on the top surface side of the insulating substrate 90a. The relay wiring elements 91a and 92a are provided separately from each other and each have a straight planar pattern extending in one direction (in the upper-lower direction in FIG. 21).

The insulating substrate 90b is provided on the top surface side of the terminal VS of the V-phase. The insulating substrate 90b is bonded to the terminal VS of the V-phase with insulating tape, for example. The insulating substrate 90b includes insulation material such as alumina. The relay wiring elements (printed wiring elements) 91b to 94b are provided on the top surface side of the insulating substrate 90b. The relay wiring elements 91b to 94b are provided separately from each other and each have a straight planar pattern extending in the direction perpendicular to the one direction (in the right-left direction in FIG. 21).

The insulating substrate 90c is provided on the top surface side of the terminal VS of the W-phase. The insulating substrate 90c is bonded to the terminal VS of the W-phase with insulating tape, for example. The insulating substrate 90c includes insulation material such as alumina. The relay wiring elements (printed wiring elements) 91c to 94c are provided on the top surface side of the insulating substrate 90c. The relay wiring elements 91c to 94c are provided separately from each other and each have a straight planar pattern extending in the direction perpendicular to the one direction (in the right-left direction in FIG. 21).

The semiconductor device according to the fifth embodiment includes the semiconductor chips 411, 421, 431, 441, 451, 461, 511, 521, 531, 541, 551, 561, 71, 76u, 76v, and 76w. The semiconductor chips 411, 421, 431, 441, 451, 461, 511, 521, 531, 541, 551, 561, 71, 76u, 76v, and 76w have substantially the same configuration as those illustrated in FIG. 16, and overlapping explanations are not repeated below.

The terminal VB of the U-phase is connected to the semiconductor chip 76u via the wire 111. The relay wiring element 91a is connected to the semiconductor chip 76u via the wire 112. The relay wiring layer 91a is connected to the relay wiring element 92b via the wire 162. The relay wiring element 92b is connected to the relay wiring element 92c via the wire 164. The relay wiring element 92c is connected to the semiconductor chip 71 via the wire 150.

The relay wiring element 92a is connected to the semiconductor chip 76u via the wire 114. The relay wiring element 92a is connected to the relay wiring element 91b via the wire 161. The relay wiring element 91b is connected to the relay wiring element 91c via the wire 163. The relay wiring element 91c is connected to the semiconductor chip 71 via the wire 149.

The terminal VS of the U-phase is connected to the emitter electrode 413 of the semiconductor chip 411 via the wire 113. The semiconductor chip 76u is connected to the gate electrode 412 of the semiconductor chip 411 via the wire 115. The semiconductor chip 76u is connected to the emitter electrode 413 of the semiconductor chip 411 via the wire 116.

The terminal VB of the V-phase is connected to the semiconductor chip 76v via the wire 121. The relay wiring element 93b is connected to the semiconductor chip 76v via the wire 122. The relay wiring layer 93b is connected to the relay wiring element 93c via the wire 165. The relay wiring element 93c is connected to the semiconductor chip 71 via the wire 151.

The relay wiring element 94b is connected to the semiconductor chip 76v via the wire 124. The relay wiring element 94b is connected to the relay wiring element 94c via the wire 166. The relay wiring element 94c is connected to the semiconductor chip 71 via the wire 152.

The terminal VS of the V-phase is connected to the emitter electrode 423 of the semiconductor chip 421 via the wire 123. The semiconductor chip 76v is connected to the gate electrode 422 of the semiconductor chip 421 via the wire 125. The semiconductor chip 76v is connected to the emitter electrode 423 of the semiconductor chip 421 via the wire 126.

The terminal VB of the W-phase is connected to the semiconductor chip 76w via the wire 131. The terminal VS of the W-phase is connected to the emitter electrode 433 of the semiconductor chip 431 via the wire 132. The semiconductor chip 71 is connected to the semiconductor chip 76w via the wires 133 and 134. The semiconductor chip 76w is connected to the gate electrode 432 of the semiconductor chip 431 via the wire 135. The semiconductor chip 76w is connected to the emitter electrode 433 of the semiconductor chip 431 via the wire 136.

The semiconductor chip 71 is connected to the terminal INHU via the wire 141. The semiconductor chip 71 is connected to the terminal INHV via the wire 142. The semiconductor chip 71 is connected to the terminal INHW via the wire 143. The semiconductor chip 71 is connected to the terminal VCC via the wire 144. The semiconductor chip 71 is connected to the terminal COM via the wire 145. The semiconductor chip 71 is connected to the terminal INLU via the wire 146. The semiconductor chip 71 is connected to the terminal INLV via the wire 147. The semiconductor chip 71 is connected to the terminal INLW via the wire 148.

The semiconductor chip 71 is connected to the gate electrode 442 of the semiconductor chip 441 via the wire 153. The semiconductor chip 71 is connected to the gate electrode 452 of the semiconductor chip 451 via the wire 154. The semiconductor chip 71 is connected to the gate electrode 462 of the semiconductor chip 461 via the wire 155.

The relation of the connection between the respective semiconductor chips 411, 421, 431, 441, 451, 461, 511, 521, 531, 541, 551, and 561 illustrated in FIG. 21 is substantially the same as that between the respective semiconductor chips 411, 421, 431, 441, 451, 461, 511, 521, 531, 541, 551, and 561 illustrated in FIG. 16, and overlapping explanations are not repeated below. The other configurations of the semiconductor device according to the fifth embodiment are substantially the same as those of the semiconductor device according to the first embodiment, and overlapping explanations are not repeated below.

The semiconductor device according to the fifth embodiment has the configuration in which the upper-arm control circuit 61 and the drive circuit 63 are provided on the different substrates independently of each other, as in the case of the semiconductor device according to the first embodiment, so as to decrease a leakage current during a standby state regardless of whether the power-supply potential Vp of the power source 14 is large. Further, the decrease in the area of the high-breakdown-voltage part can contribute to a decrease in circuit area.

### Sixth Embodiment

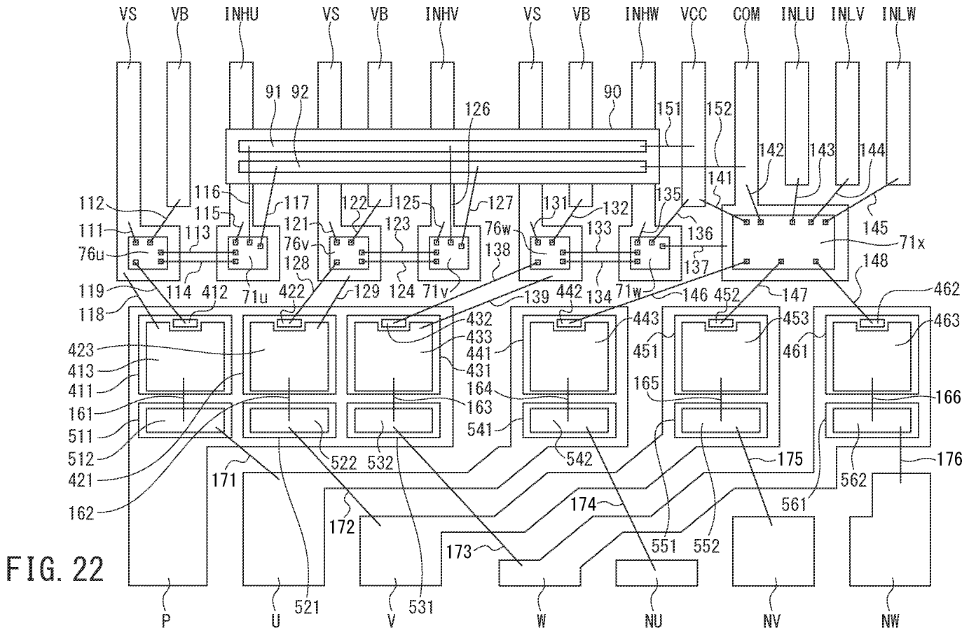

FIG. 22 is a view illustrating an example of a packaged configuration of a semiconductor device according to a sixth embodiment. As illustrated in FIG. 22, the semiconductor device according to the sixth embodiment differs from the semiconductor device according to the first embodiment illustrated in FIG. 16 in that the semiconductor chips 71u, 71v, and 71w provided with the upper-arm control circuit 61 and the MOS transistors 52a and 52b of the level-shift circuit 62 of the respective semiconductor devices 31 to 33 are provided separately from the semiconductor chip 71x provided with the lower-arm control circuit 34, and further in including a wired substrate including the insulating substrate 90 and the relay wiring elements 91 and 92.

The semiconductor device according to the sixth embodiment includes the respective terminals VB of the U-phase, the V-phase, and the W-phase, the respective terminals VS of the U-phase, the V-phase, and the W-phase, and the terminals INHU, INHV, INHW, VCC, COM, INLU, INLV, INLW, P, U, V, W, NU, NV, and NW.

The insulating substrate 90 is provided on the top surface side of each of the terminals VS and VB of the V-phase, the terminals VS and VB of the W-phase, and the terminals INHU, INHV, and INHW. The relay wiring elements 91 and 92 are provided on the top surface side of the insulating substrate 90. The insulating substrate 90 and the relay wiring elements 91 and 92 implement the wired substrate. The relay wiring elements 91 and 92 are provided separately from each other and each have a straight planar pattern extending in one direction (in the right-left direction in FIG. 21).

The semiconductor device according to the sixth embodiment includes the semiconductor chips 411, 421, 431, 441, 451, 461, 511, 521, 531, 541, 551, 561, 71u, 71v, 71w, 71x, 76u, 76v, and 76w. The semiconductor chips 411, 421, 431, 441, 451, 461, 511, 521, 531, 541, 551, 561, 71u, 71v, 71w, 71x, 76u, 76v, and 76w have substantially the same configuration as those illustrated in FIG. 16, and overlapping explanations are not repeated below.

The semiconductor chip 76u is provided on the top surface side of the terminal VS of the U-phase. The semiconductor chip 71u is provided on the top surface side of the terminal INHU. The semiconductor chip 76v is provided on the top surface side of the terminal VS of the V-phase. The semiconductor chip 71v is provided on the top surface side of the terminal INHV. The semiconductor chip 76w is provided on the top surface side of the terminal VS of the W-phase. The semiconductor chip 71w is provided on the top surface side of the terminal INHW. The semiconductor chip 71x is provided on the top surface side of the terminal COM.

The semiconductor chip 76u is connected to the terminal VS of the U-phase via the wire 111. The terminal VS of the U-phase is connected to the emitter electrode 413 of the semiconductor chip 411 via the wire 118. The semiconductor chip 76u is connected to the terminal VB of the U-phase via the wire 112. The semiconductor chip 76u is connected to the semiconductor chip 71u via the wires 113 and 114. The semiconductor chip 76u is connected to the gate electrode 412 of the semiconductor chip 411 via the wire 119.

The semiconductor chip 71u is connected to the terminal INHU via the wire 115. The semiconductor chip 71u is connected to the relay wiring element 91 via the wire 116. The relay wiring element 91 is connected to the terminal VCC via the wire 151. The semiconductor chip 71u is connected to the relay wiring element 92 via the wire 117. The relay wiring element 92 is connected to the terminal COM via the wire 152.

The semiconductor chip 76v is connected to the terminal VS of the V-phase via the wire 121. The terminal VS of the V-phase is connected to the emitter electrode 423 of the semiconductor chip 421 via the wire 129. The semiconductor chip 76v is connected to the terminal VB of the V-phase via the wire 122. The semiconductor chip 76v is connected to the semiconductor chip 71v via the wires 123 and 124. The semiconductor chip 76v is connected to the gate electrode 422 of the semiconductor chip 421 via the wire 128.

The semiconductor chip 71v is connected to the terminal INHV via the wire 125. The semiconductor chip 71v is connected to the relay wiring element 91 via the wire 126. The semiconductor chip 71v is connected to the relay wiring element 92 via the wire 127.

The semiconductor chip 76w is connected to the terminal VS of the W-phase via the wire 131. The terminal VS of the W-phase is connected to the emitter electrode 433 of the semiconductor chip 431 via the wire 139. The semiconductor chip 76w is connected to the terminal VB of the W-phase via the wire 132. The semiconductor chip 76w is connected to the semiconductor chip 71w via the wires 133 and 134. The semiconductor chip 76w is connected to the gate electrode 432 of the semiconductor chip 431 via the wire 138.

The semiconductor chip 71w is connected to the terminal INHW via the wire 135. The semiconductor chip 71w is connected to the terminal VCC via the wire 136. The semiconductor chip 71v is connected to the terminal COM via the wire 137.

The semiconductor chip 71 is connected to the terminal VCC via the wire 141. The semiconductor chip 71 is connected to the terminal COM via the wire 142. The semiconductor chip 71 is connected to the terminal INLU via the wire 143. The semiconductor chip 71 is connected to the terminal INLV via the wire 144. The semiconductor chip 71 is connected to the terminal INLW via the wire 145.

The semiconductor chip 71 is connected to the gate electrode 442 of the semiconductor chip 441 via the wire 146. The semiconductor chip 71 is connected to the gate electrode 452 of the semiconductor chip 451 via the wire 147. The semiconductor chip 71 is connected to the gate electrode 462 of the semiconductor chip 461 via the wire 148.

The relation of the connection between the respective semiconductor chips 411, 421, 431, 441, 451, 461, 511, 521, 531, 541, 551, and 561 illustrated in FIG. 22 is substantially the same as that between the respective semiconductor chips 411, 421, 431, 441, 451, 461, 511, 521, 531, 541, 551, and 561 illustrated in FIG. 16, and overlapping explanations are not repeated below. The other configurations of the semiconductor device according to the sixth embodiment are substantially the same as those of the semiconductor device according to the first embodiment, and overlapping explanations are not repeated below.

The semiconductor device according to the sixth embodiment has the configuration in which the upper-arm control circuit 61 and the drive circuit 63 are provided on the different substrates independently of each other, as in the case of the semiconductor device according to the first embodiment, so as to decrease a leakage current during a standby state regardless of whether the power-supply potential Vp of the power source 14 is large. Further, the decrease in the area of the high-breakdown-voltage part can contribute to a decrease in circuit area.

### Seventh Embodiment

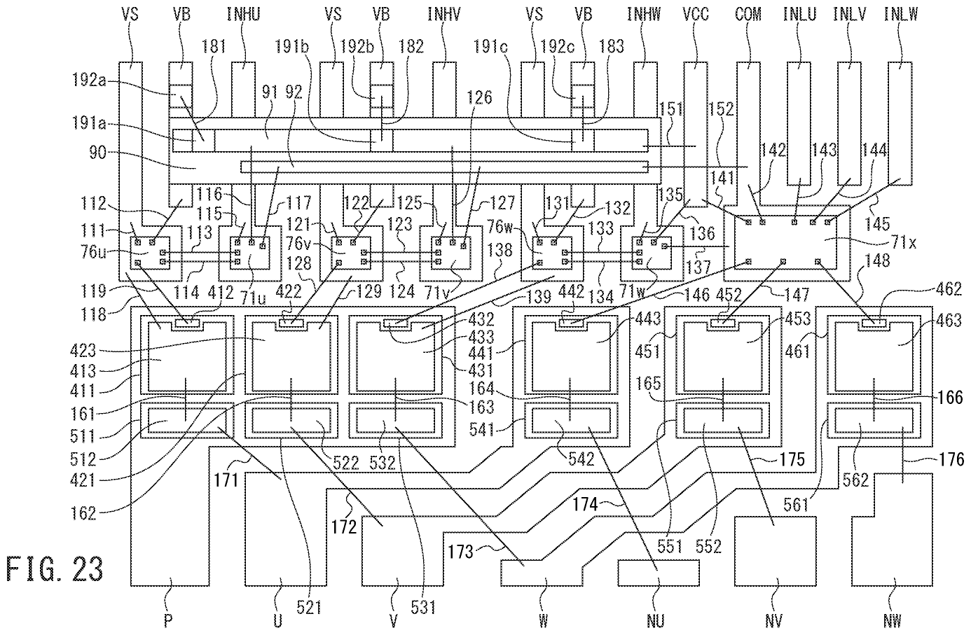

FIG. 23 is a view illustrating an example of a packaged configuration of a semiconductor device according to a seventh embodiment. As illustrated in FIG. 23, the semiconductor device according to the seventh embodiment differs from the semiconductor device according to the sixth embodiment illustrated in FIG. 22 in further including semiconductor chips 191a, 191b, and 191c provided on the top surface side of the relay wiring element 91 and in including semiconductor chips 192a, 192b, and 192c provided on the top surfaces side of the respective terminals VB of the U-phase, the V-phase, and the W-phase.

The respective semiconductor chips 191a, 191b, and 191c are provided with a vertical chip resistor. The respective semiconductor chips 192a, 192b, and 192c are provided with a diode such as a vertical Schottky barrier diode or a p-n junction diode.

The semiconductor chip 191a is connected to the semiconductor chip 192a via a wire 181. The semiconductor chip 191b is connected to the semiconductor chip 192b via a wire 182. The semiconductor chip 191c is connected to the semiconductor chip 192c via a wire 183.

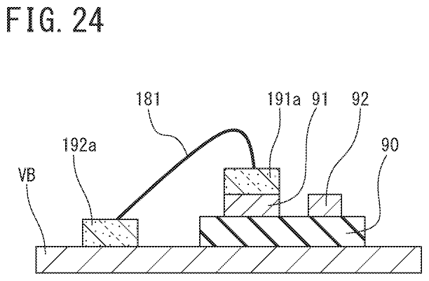

FIG. 24 is a schematic cross-sectional view illustrating a region including the semiconductor chips 191a and 192a. As illustrated in FIG. 24, the semiconductor chip 192a and the insulating substrate 90 are provided on the top surface side of the terminal VB of the U-phase. The respective relay wiring elements 91 and 92 are provided on the top surface side of the insulating substrate 90. The relay wiring elements 91 and 92 are provided separately from each other and each have a straight planar pattern so as to extend parallel to each other in one direction, which is a backward direction of the sheet in FIG. 24. The semiconductor chip 191a is provided on the top surface side of the relay wiring element 91. The semiconductor chip 191a is connected to the semiconductor chip 192a via the wire 181.

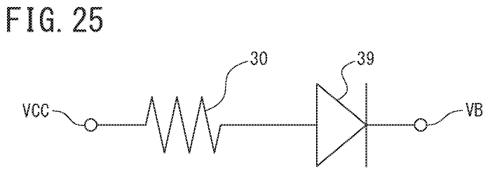

FIG. 25 is an equivalent circuit diagram of the semiconductor chips 191a and 192a. The semiconductor chip 191a corresponds to a resistor 30, and the semiconductor chip 192a corresponds to a diode 39. One end of the resistor 30 is connected to the terminal VCC, and the other end is connected to the anode of the diode 39. The terminal VB is connected to the cathode of the diode 39.

The other configurations of the semiconductor device according to the seventh embodiment are substantially the same as those of the semiconductor device according to the sixth embodiment illustrated in FIG. 22, and overlapping explanations are not repeated below.

The semiconductor device according to the seventh embodiment has the configuration in which the upper-arm control circuit 61 and the drive circuit 63 are provided on the different substrates independently of each other, as in the case of the semiconductor device according to the first embodiment, so as to decrease a leakage current during a standby state regardless of whether the power-supply potential Vp of the power source 14 is large. Further, the decrease in the area of the high-breakdown-voltage part can contribute to a decrease in circuit area.

### Eighth Embodiment

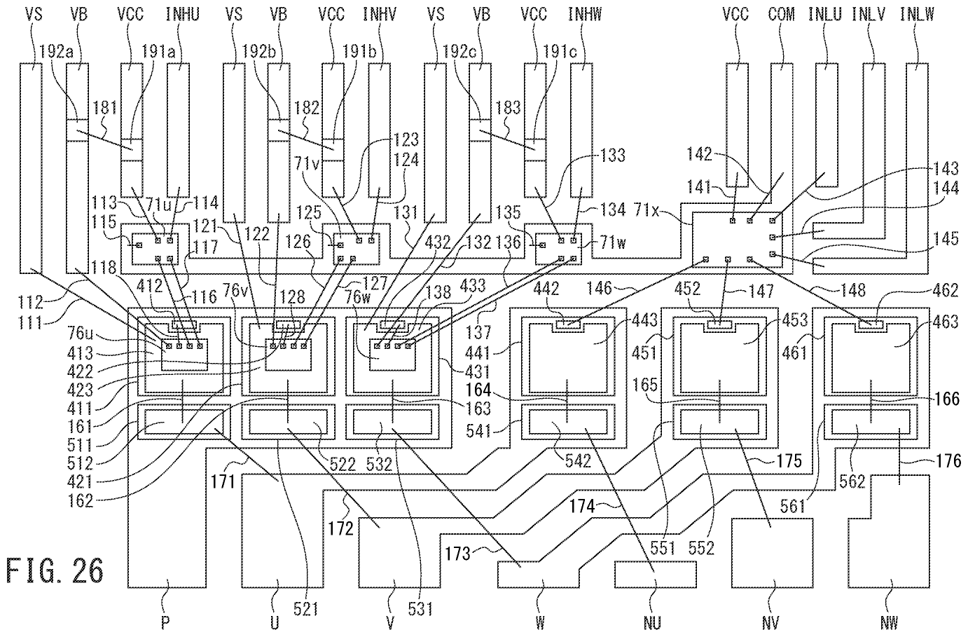

FIG. 26 is a view illustrating an example of a packaged configuration of a semiconductor device according to an eighth embodiment. As illustrated in FIG. 26, the semiconductor device according to the eighth embodiment differs from the semiconductor device according to the third embodiment illustrated in FIG. 19 in further including the semiconductor chips 191a, 191b, and 191c provided on the top surface sides of the respective terminals VCC of the U-phase, the V-phase, and the W-phase and in including the semiconductor chips 192a, 192b, and 192c provided on the top surface sides of the respective terminals VB of the U-phase, the V-phase, and the W-phase.

The respective semiconductor chips 191a, 191b, and 191c are provided with a vertical chip resistor. The respective semiconductor chips 192a, 192b, and 192c are provided with a diode such as a vertical Schottky barrier diode or a p-n junction diode.

The semiconductor chip 191a is connected to the semiconductor chip 192a via the wire 181. The semiconductor chip 191b is connected to the semiconductor chip 192b via the wire 182. The semiconductor chip 191c is connected to the semiconductor chip 192c via the wire 183.

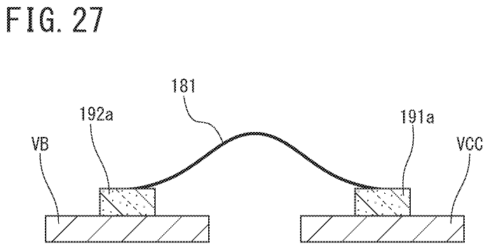

FIG. 27 is a cross-sectional view illustrating a region including the semiconductor chips 191a and 192a. As illustrated in FIG. 27, the semiconductor chip 192a is provided on the top surface side of the terminal VB of the U-phase. The semiconductor chip 191a is provided on the top surface side of the terminal VCC of the U-phase. The semiconductor chip 191a is connected to the semiconductor chip 192a via the wire 181. The equivalent circuit of the semiconductor chips 191a and 192a is common to that illustrated in FIG. 25.

The other configurations of the semiconductor device according to the eighth embodiment are substantially the same as those of the semiconductor device according to the third embodiment illustrated in FIG. 19, and overlapping explanations are not repeated below.

The semiconductor device according to the eighth embodiment has the configuration in which the upper-arm control circuit 61 and the drive circuit 63 are provided on the different substrates independently of each other, as in the case of the semiconductor device according to the first embodiment, so as to decrease a leakage current during a standby state regardless of whether the power-supply potential Vp of the power source 14 is large. Further, the decrease in the area of the high-breakdown-voltage part can contribute to a decrease in circuit area.

### Ninth Embodiment

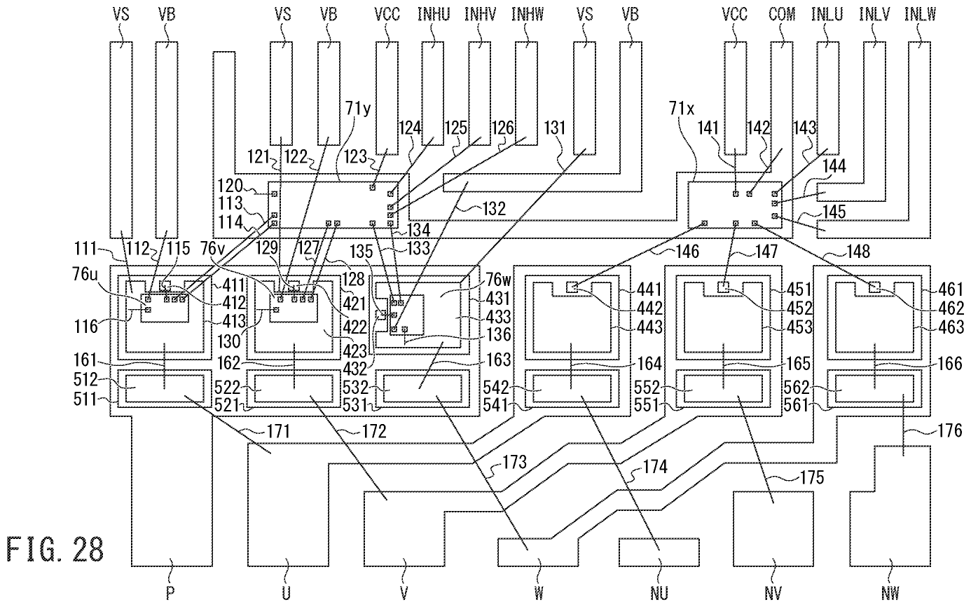

FIG. 28 is a view illustrating an example of a packaged configuration of a semiconductor device according to a ninth embodiment. As illustrated in FIG. 28, the semiconductor device according to the ninth embodiment differs from the semiconductor device according to the third embodiment illustrated in FIG. 19 in that a semiconductor chip 71y is provided on the top surface side of the terminal COM, instead of the semiconductor chips 71u, 71v, and 71w. The semiconductor chip 71y has a configuration in which the semiconductor devices 711 to 713 are integrated together on the common substrate.

The semiconductor device according to the ninth embodiment includes the respective terminals VB of the U-phase, the V-phase, and the W-phase, the respective terminals VS of the U-phase, the V-phase, and the W-phase, the terminal VCC common to the U-phase, the V-phase, and the W-phase, and the terminals INHU, INHV, INHW, VCC, COM, INLU, INLV, INLW, P, U, V, W, NU, NV, and NW. The terminal COM has an L-shaped planar pattern. The terminal COM is provided to extend across the respective terminals VB of the V-phase and the W-phase, the respective terminals VS of the V-phase and the W-phase, the terminal VCC common to the U-phase, the V-phase, and the W-phase, the terminals INHU, INHV, INHW, and VCC, and the semiconductor chips 421, 431, 441, and 451.

The semiconductor device according to the ninth embodiment includes the semiconductor chips 411, 421, 431, 441, 451, 461, 511, 521, 531, 541, 551, 561, 71x, 71y, 76u, 76v, and 76w. While the present embodiment is illustrated with the case in which the semiconductor chip 431 is rotated at 90 degrees in the counterclockwise direction with respect to the semiconductor chips 411 and 421 so as to facilitate wire bonding, the orientation of the semiconductor chip 431 is not limited to this case. The semiconductor chips 411, 421, 431, 441, 451, 461, 511, 521, 531, 541, 551, and 561 have substantially the same configuration as those illustrated in FIG. 19, and overlapping explanations are not repeated below.

The semiconductor chips 76u, 76v, and 76w are provided on the top surface sides of the corresponding semiconductor chips 411, 421, and 431 so as to implement the Chip-on-Chip (CoC) configuration. The respective rear surfaces of the semiconductor chips 76u, 76v, and 76w are bonded to the top surfaces of the semiconductor chips 411, 421, and 431 with insulating tape, for example. The rear surfaces of the semiconductor chips 76u, 76v, and 76w may be electrically connected to the emitter electrodes 413, 423, and 433 of the semiconductor chips 411, 421, and 431. The semiconductor chip 76u is provided with the semiconductor device 761. The semiconductor chips 76v is provided with the semiconductor device 762. The semiconductor chip 76w is provided with the semiconductor device 763.

The terminal VS of the U-phase is connected to the emitter electrode 413 of the semiconductor chip 411 via the wire 111. The terminal VB of the U-phase is connected to the semiconductor chip 76u via the wire 112. The semiconductor chip 71y is connected to the semiconductor chip 76u via the wires 113 and 114. The semiconductor chip 76u is connected to the gate electrode 412 of the semiconductor chip 411 via the wire 115. The semiconductor chip 76u is connected to the emitter electrode 413 of the semiconductor chip 411 via the wire 116.

The terminal VS of the V-phase is connected to the emitter electrode 423 of the semiconductor chip 421 via the wire 121. The terminal VB of the V-phase is connected to the semiconductor chip 76v via the wire 122. The semiconductor chip 71y is connected to the terminal COM via the wire 120. The semiconductor chip 71y is connected to the terminal VCC common to the U-phase, the V-phase, and the W-phase via the wire 123. The semiconductor chip 71y is connected to the terminal INHU via the wire 124. The semiconductor chip 71y is connected to the terminal INHV via the wire 125. The semiconductor chip 71y is connected to the terminal INHW via the wire 126. The semiconductor chip 71y is connected to the semiconductor chip 76v via the wires 127 and 128. The semiconductor chip 76v is connected to the gate electrode 422 of the semiconductor chip 421 via the wire 129. The semiconductor chip 76v is connected to the emitter electrode 423 of the semiconductor chip 421 via the wire 130.

The terminal VS of the W-phase is connected to the emitter electrode 433 of the semiconductor chip 431 via the wire 131. The terminal VB of the W-phase is connected to the semiconductor chip 76w via the wire 132. The semiconductor chip 71y is connected to the semiconductor chip 76w via the wires 133 and 134. The semiconductor chip 76w is connected to the gate electrode 432 of the semiconductor chip 431 via the wire 135. The semiconductor chip 76w is connected to the emitter electrode 433 of the semiconductor chip 431 via the wire 136.

The semiconductor chip 71x is provided on the top surface side of the terminal COM. The semiconductor chip 71x is provided with the lower-arm control circuit 34. The semiconductor chip 71x is connected to the terminal VCC via the wire 141. The semiconductor chip 71x is connected to the terminal COM via the wire 142. The semiconductor chip 71x is connected to the terminal INLU via the wire 143. The semiconductor chip 71x is connected to the terminal INLV via the wire 144. The semiconductor chip 71x is connected to the terminal INLW via the wire 145. The semiconductor chip 71x is connected to the gate electrode 442 of the semiconductor chip 441 via the wire 146. The semiconductor chip 71x is connected to the gate electrode 452 of the semiconductor chip 451 via the wire 147. The semiconductor chip 71x is connected to the gate electrode 462 of the semiconductor chip 461 via the wire 148.

The relation of the connection between the respective semiconductor chips 411, 421, 431, 441, 451, 461, 511, 521, 531, 541, 551, and 561 illustrated in FIG. 28 is substantially the same as that between the respective semiconductor chips 411, 421, 431, 441, 451, 461, 511, 521, 531, 541, 551, and 561 illustrated in FIG. 19, and overlapping explanations are not repeated below. The other configurations of the semiconductor device according to the ninth embodiment are substantially the same as those of the semiconductor device according to the third embodiment, and overlapping explanations are not repeated below.

The semiconductor device according to the ninth embodiment has the configuration in which the upper-arm control circuit 61 and the drive circuit 63 are provided on the different substrates independently of each other, as in the case of the semiconductor device according to the first embodiment, so as to decrease a leakage current during a standby state regardless of whether the power-supply potential Vp of the power source 14 is large. In addition, the decrease in the area of the high-breakdown-voltage part can contribute to a decrease in circuit area. Further, the configuration, in which the semiconductor chips 76u, 76v, and 76w provided with the drive circuit 63 are provided on the top surfaces of the corresponding semiconductor chips 411, 421, and 431 so as to implement the Chip-on-Chip (CoC) configuration, does not need to ensure insulation between the respective chips because the substrate potential of the drive circuit 63 when set to the VS potential is equal to the chip-surface potential of the semiconductor chips 411, 421, and 431 of the respective switching element 41 to 43, so as to achieve a decrease in the packaged area accordingly. Further, the integration of the semiconductor devices 711 to 713 on the semiconductor chip 71y can also contribute to the decrease in the packaged area.

### Tenth Embodiment

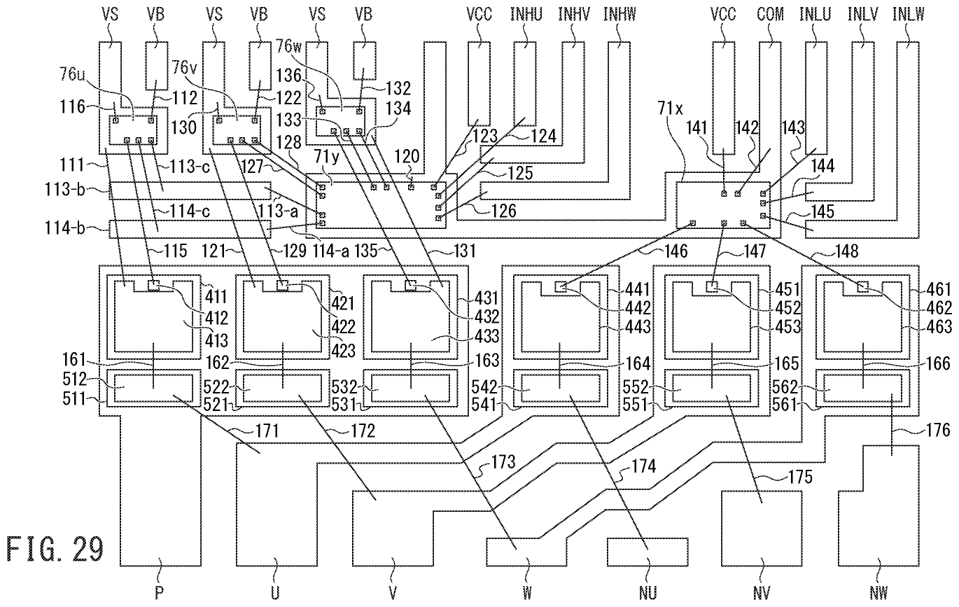

FIG. 29 is a view illustrating an example of a packaged configuration of a semiconductor device according to a tenth embodiment. As illustrated in FIG. 29, the semiconductor device according to the tenth embodiment differs from the semiconductor device according to the ninth embodiment illustrated in FIG. 28 in that the semiconductor chips 76u, 76v, and 76w are provide on the top surface sides of the respective terminals VS of the U-phase, the V-phase, and the W-phase, instead of the top surface sides of the respective semiconductor chips 411, 421, and 431. The semiconductor chip 71y has a configuration in which the semiconductor devices 711 to 713 are integrated together on the common substrate, as in the case illustrated in FIG. 28.

The semiconductor device according to the tenth embodiment includes the respective terminals VB of the U-phase, the V-phase, and the W-phase, the respective terminals VS of the U-phase, the V-phase, and the W-phase, the terminal VCC common to the U-phase, the V-phase, and the W-phase, and the terminals INHU, INHV, INHW, VCC, COM, INLU, INLV, INLW, P, U, V, W, NU, NV, and NW. The terminal COM has an L-shaped planar pattern. The terminal COM is provided to extend across the terminal VB of the W-phase, the terminal VS of the W-phase, the terminal VCC common to the U-phase, the V-phase, and the W-phase, the terminals INHU, INHV, INHW, and VCC, and the semiconductor chips 421, 431, 441, and 451.

The semiconductor device according to the tenth embodiment includes the semiconductor chips 411, 421, 431, 441, 451, 461, 511, 521, 531, 541, 551, 561, 71x, 71y, 76u, 76v, and 76w. The semiconductor chips 411, 421, 431, 441, 451, 461, 511, 521, 531, 541, 551, and 561 have substantially the same configuration as those illustrated in FIG. 19, and overlapping explanations are not repeated below.

The semiconductor chips 76u, 76v, and 76w are provided on the top surface sides of the corresponding VS terminals of the U-phase, the V-phase, and the W-phase. The respective rear surfaces of the semiconductor chips 76u, 76v, and 76w are bonded to the top surfaces of the VS terminals via insulating tape, for example. The respective rear surfaces of the semiconductor chips 76u, 76v, and 76w may be electrically connected to the respective terminals VS.

The terminal VS of the U-phase is connected to the emitter electrode 413 of the semiconductor chip 411 via the wire 111. The terminal VB of the U-phase is connected to the semiconductor chip 76u via the wire 112. The semiconductor chip 71y is connected to the semiconductor chip 76u via wires 113-a and 114-a, relay wires 113-b and 114-b, and wires 113-c and 114-c. The semiconductor chip 76u is connected to the gate electrode 412 of the semiconductor chip 411 via the wire 115. The semiconductor chip 76u is connected to the terminal VS of the U-phase via the wire 116.

The terminal VS of the V-phase is connected to the emitter electrode 423 of the semiconductor chip 421 via the wire 121. The terminal VB of the V-phase is connected to the semiconductor chip 76v via the wire 122. The semiconductor chip 71y is connected to the terminal COM via the wire 120. The semiconductor chip 71y is connected to the terminal VCC common to the U-phase, the V-phase, and the W-phase via the wire 123. The semiconductor chip 71y is connected to the terminal INHU via the wire 124. The semiconductor chip 71y is connected to the terminal INHV via the wire 125. The semiconductor chip 71y is connected to the terminal INHW via the wire 126. The semiconductor chip 71y is connected to the semiconductor chip 76v via the wires 127 and 128. The semiconductor chip 76v is connected to the gate electrode 422 of the semiconductor chip 421 via the wire 129. The semiconductor chip 76v is connected to the terminal VS of the V-phase via the wire 130.

The terminal VS of the W-phase is connected to the emitter electrode 433 of the semiconductor chip 431 via the wire 131. The terminal VB of the W-phase is connected to the semiconductor chip 76w via the wire 132. The semiconductor chip 71y is connected to the semiconductor chip 76w via the wires 133 and 134. The semiconductor chip 76w is connected to the gate electrode 432 of the semiconductor chip 431 via the wire 135. The semiconductor chip 76w is connected to the terminal VS of the W-phase via the wire 136.

The semiconductor chip 71x is provided on the top surface side of the terminal COM. The semiconductor chip 71x is provided with the lower-arm control circuit 34. The semiconductor chip 71x is connected to the terminal VCC via the wire 141. The semiconductor chip 71x is connected to the terminal COM via the wire 142. The semiconductor chip 71x is connected to the terminal INLU via the wire 143. The semiconductor chip 71x is connected to the terminal INLV via the wire 144. The semiconductor chip 71x is connected to the terminal INLW via the wire 145. The semiconductor chip 71x is connected to the gate electrode 442 of the semiconductor chip 441 via the wire 146. The semiconductor chip 71x is connected to the gate electrode 452 of the semiconductor chip 451 via the wire 147. The semiconductor chip 71x is connected to the gate electrode 462 of the semiconductor chip 461 via the wire 148.

The relation of the connection between the respective semiconductor chips 411, 421, 431, 441, 451, 461, 511, 521, 531, 541, 551, and 561 illustrated in FIG. 29 is substantially the same as that between the respective semiconductor chips 411, 421, 431, 441, 451, 461, 511, 521, 531, 541, 551, and 561 illustrated in FIG. 19, and overlapping explanations are not repeated below. The other configurations of the semiconductor device according to the tenth embodiment are substantially the same as those of the semiconductor device according to the third embodiment, and overlapping explanations are not repeated below.

The semiconductor device according to the tenth embodiment has the configuration in which the upper-arm control circuit 61 and the drive circuit 63 are provided on the different substrates independently of each other, as in the case of the semiconductor device according to the first embodiment, so as to decrease a leakage current during a standby state regardless of whether the power-supply potential Vp of the power source 14 is large. In addition, the decrease in the area of the high-breakdown-voltage part can contribute to a decrease in circuit area. Further, the integration of the semiconductor devices 711 to 713 on the semiconductor chip 71y can also contribute to the decrease in the packaged area.

### Other Embodiments

As described above, the present disclosure has been described according to the first to tenth embodiments, but it should not be understood that the description and drawings implementing a portion of this disclosure limit the present disclosure. Various alternative embodiments of the present disclosure, examples, and operational techniques will be apparent to those skilled in the art from this disclosure.

The configurations disclosed in the first to tenth embodiments may be combined as appropriate within a range that does not contradict with the scope of the respective embodiments. As described above, the invention includes various embodiments of the present disclosure and the like not described herein. Therefore, the scope of the present disclosure is defined only by the technical features specifying the present disclosure, which are prescribed by claims, the words and terms in the claims shall be reasonably construed from the subject matters recited in the present specification.

What is claimed is:

1. A semiconductor device comprising:
a first switching element provided in a first semiconductor chip;
a first control circuit provided in a second semiconductor chip so as to output a signal for controlling the first switching element;
a level-shift circuit provided to convert a potential of the signal output from the first control circuit; and
a drive circuit provided in a third semiconductor chip so as to drive the first switching element in accordance with the signal with the potential converted by the level-shift circuit,
wherein the third semiconductor chip is provided on the first semiconductor chip.

2. The semiconductor device of claim 1, wherein:
the level-shift circuit includes a MOS transistor and a resistor;
the MOS transistor is provided in the second semiconductor chip; and
the resistor is provided in the third semiconductor chip.

3. The semiconductor device of claim 1, further comprising:
a second switching element provided in a fourth semiconductor chip; and
a second control circuit provided to output a signal for controlling the second switching element.

4. The semiconductor device of claim 3, wherein the second control circuit is provided in the second semiconductor chip.

5. The semiconductor device of claim 4, wherein:
the semiconductor device comprises a plurality of the first switching elements, a plurality of the first control circuits, a plurality of the drive circuits, and a plurality of the second switching elements;
the semiconductor device further comprises a plurality of the first semiconductor chips, a plurality of the third semiconductor chips, and a plurality of the fourth semiconductor chips;
the plural first switching elements are provided in the plural first semiconductor chips;
the plural first control circuits are provided in the common second semiconductor chip together with the second control circuit;
the plural drive circuits are provided in the plural fourth semiconductor chips; and
the plural second switching elements are provided in the plural fourth semiconductor chips.

6. The semiconductor device of claim 3, wherein the second control circuit is provided in a fifth semiconductor chip.

7. The semiconductor device of claim 6, wherein:
the semiconductor device comprises a plurality of the first switching elements, a plurality of the first control circuits, a plurality of the drive circuits, and a plurality of the second switching elements;
the semiconductor device further comprises a plurality of the first semiconductor chips, a plurality of the second semiconductor chips, a plurality of the third semiconductor chips, and a plurality of the fourth semiconductor chips;
the plural first switching elements are provided in the plural first semiconductor chips;
the plural first control circuits are provided in the plural second semiconductor chips;
the plural drive circuits are provided in the plural third semiconductor chips; and
the plural second switching elements are provided in the plural fourth semiconductor chips.

8. The semiconductor device of claim 6, wherein:
the semiconductor device comprises a plurality of the first switching elements, a plurality of the first control circuits, a plurality of the drive circuits, and a plurality of the second switching elements;
the semiconductor device further comprises a plurality of the first semiconductor chips, a plurality of the third semiconductor chips, and a plurality of the fourth semiconductor chips;
the plural first switching elements are provided in the plural first semiconductor chips;
the plural first control circuits are provided in the common second semiconductor chip;
the plural drive circuits are provided in the plural third semiconductor chips; and
the plural second switching elements are provided in the plural fourth semiconductor chips.

9. The semiconductor device of claim 6, further comprising:
a plurality of terminals electrically connected to the drive circuit; and
a wired substrate arranged on the plural terminals,
wherein the second semiconductor chip is connected to the fifth semiconductor chip via the wired substrate.

10. The semiconductor device of claim 4, further comprising:
a plurality of terminals electrically connected to the drive circuit; and
a wired substrate arranged on the plural terminals,
wherein the third semiconductor chip is connected to the second semiconductor chip via the wired substrate.

11. A semiconductor device comprising:
a first switching element provided in a first semiconductor chip;
a first control circuit provided in a second semiconductor chip so as to output a signal for controlling the first switching element;
a level-shift circuit provided to convert a potential of the signal output from the first control circuit;
a drive circuit provided in a third semiconductor chip so as to drive the first switching element in accordance with the signal with the potential converted by the level-shift circuit; and
a relay wiring element arranged between the first semiconductor chip and the third semiconductor chip so as to be electrically connected to at least any of the first semiconductor chip, the second semiconductor chip, and the third semiconductor chip.

12. The semiconductor device of claim 11, further comprising a plurality of terminals electrically connected to the drive circuit,
wherein the relay wiring element is arranged between the plural terminals.

13. The semiconductor device of claim 11, further comprising:
a plurality of terminals electrically connected to the drive circuit;
a substrate-supporting frame arranged between the plural terminals; and
an insulating substrate provided on the substrate-supporting frame,
wherein the relay wiring element is provided on the insulating substrate.

14. The semiconductor device of claim 11, wherein the first semiconductor chip is electrically connected to the third semiconductor chip via the relay wiring element.

15. The semiconductor device of claim 11, wherein the second semiconductor chip is electrically connected to the third semiconductor chip via the relay wiring element.

16. The semiconductor device of claim 11, further comprising:
a second switching element provided in a fourth semiconductor chip; and
a second control circuit provided to output a signal for controlling the second switching element provided in a fifth semiconductor chip,
wherein
the semiconductor device comprises a plurality of the first switching elements, a plurality of the first control circuits, a plurality of the drive circuits, a plurality of the second switching elements, and a plurality of the second control circuits,
the semiconductor device further comprises a plurality of the first semiconductor chips, a plurality of the third semiconductor chips, and a plurality of the fourth semiconductor chips,
the plural first switching elements are provided in the plural first semiconductor chips,
the plural first control circuits are provided in the common second semiconductor chip,
the plural drive circuits are provided in the plural third semiconductor chips, the plural second switching elements are provided in the plural fourth semiconductor chips, and
the relay wiring element is arranged between at least one of the first semiconductor chips and one of the third semiconductor chips.

17. A semiconductor device comprising:
a first switching element provided in a first semiconductor chip;
a first control circuit provided in a second semiconductor chip so as to output a signal for controlling the first switching element;
a level-shift circuit provided to convert a potential of the signal output from the first control circuit;
a drive circuit provided in a third semiconductor chip so as to drive the first switching element in accordance with the signal with the potential converted by the level-shift circuit;
a plurality of terminals electrically connected to the drive circuit; and
a wired substrate arranged on the plural terminals and electrically connected to at least either the second semiconductor chip or the third semiconductor chip.

18. The semiconductor device of claim 17, wherein the wired substrate includes:
an insulating substrate arranged across the plural terminals; and
a relay wiring element provided on the insulating substrate.

19. The semiconductor device of claim 17, wherein the wired substrate includes:
a plurality of insulating substrates provided on the respective terminals; and
a plurality of relay wiring elements provided on the respective insulating substrates.
